(19) United States
(12) Patent Application Publication
(10) Pub. No.: US 2026/0020212 A1
(43) Pub. Date: Jan. 15, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Hong-Chih Chen, Changhua County (TW); Meng-I LU, Taichung City (TW); Jin Aun NG, Hsinchu City (TW); Fu-Hsiang SU, Zhubei City (TW); Shih-Hsun CHANG, Hsinchu City (TW); Jhon Jhy LIAW, Hsinchu County (TW)

(73) Assignee: TAIWAN SEMICONDUCTOR MANUFACTURING COMPANY LTD., Hsinchu (TW)

(21) Appl. No.: 18/767,203

(22) Filed: Jul. 9, 2024

(51) Int. Cl. H10B 10/00

(52) U.S. Cl. CPC H10B 10/125

(57) ABSTRACT

A method includes forming first and second gate patterns extending across a channel pattern; forming source/drain patterns adjoining the channel pattern; depositing a dielectric layer over the source/drain patterns; performing an etching process on the dielectric layer, the first and second gate patterns, and the channel pattern to form first and second trenches, wherein when viewed from above, the first trench extends longitudinally along the first channel pattern and intersects the first and second gate patterns, thereby severing the first and second gate patterns, and the second trench initiates from the first trench, takes the place of a first segment of the first gate pattern, and severs the channel pattern originally beneath the first segment of the first gate pattern; filling a dielectric material in the first and second trenches to form a gate isolation structure.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a static random access memory (SRAM) cell in accordance with some embodiments of the present disclosure.

FIGS. 2A and 13-15 illustrate cell array layout diagrams of a SRAM circuit in accordance with some embodiments of the present disclosure.

FIG. 2B is a local enlarged view of a region in FIG. 2A in accordance with some embodiments of the present disclosure.

FIG. 3 illustrates a perspective view of an example nano-FET device in accordance with some embodiments of the present disclosure.

FIGS. 4A-4C illustrate schematic cross-sectional views obtained from reference cross-sections C1-C1′, C2-C2′, and C3-C3′ in FIG. 2A; respectively.

FIGS. 5A-12D illustrate schematic views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

In some embodiments, in SRAM, the continuous poly on oxide definition edge (CPODE) pattern can define the boundaries of active regions in the semiconductor device. The end of this CPODE line can be vulnerable due to its integration with cut metal gate (CMG), which is used to enhance the functionality of the gates in transistor architectures. However, the critical dimension (CD) and the precise spacing required at the end of the CPODE line when interfaced with the CMG may pose risks of “cut fail” when the etching or cutting process used to segment the gate material into distinct gates for individual transistors is imprecise or incomplete. This inaccuracy can lead to electrical failures due to short circuits or incomplete isolation between adjacent transistor gates. Alongside the risks associated with cut fail, the peeling of layers at the CPODE line end is another concern. Peeling may result from inadequate adhesion of the photo resist film layers during, exacerbated by the stress and strain imposed during the CMG process.

Therefore, the present disclosure in various embodiments provides an improved SRAM layout with a CMG structure featuring, such as H-shape, T-shape, cross-shape, and square top view profiles, can enhance the reliability and performance of semiconductor devices. By adjusting the CMG structure profiles, the tolerance window for manufacturing issues like peeling and cut fails can be enlarged, leading to more robust gate structures. The CMG structure of the present disclosure can helps minimize CPD layout effects and mitigate metal boundary effects between pass-gate and pull-down transistors, thus improving circuit reliability and performance consistency.

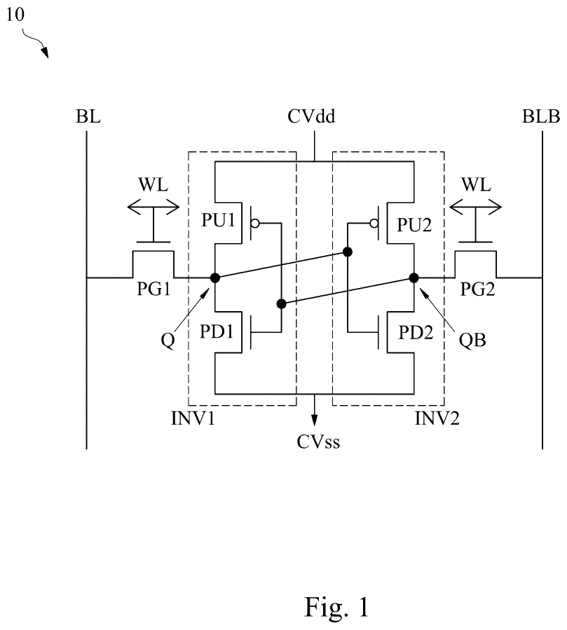

Reference is made to FIG. 1. FIG. 1 is a circuit diagram of a static random access memory (SRAM) cell Cell-1 in accordance with some embodiments of the present disclosure. As shown in FIG. 1, the SRAM cell 10 includes pull-up transistors PU1 and PU2, which are of first conductivity type, and pull-down transistors PD1 and PD2 and pass-gate transistors PG1 and PG2, which are second conductivity type opposite to the first conductivity type. By way of example and not limitation, the pull-up transistors PU1 and PU2 can be p-type Metal-Oxide-Semiconductor (PMOS) transistors, and pull-down transistors PD1 and PD2 and pass-gate transistors PG1 and PG2 can be n-type Metal-Oxide-Semiconductor (NMOS) transistors.

The gates of pass-gate transistors PG1 and PG2 are controlled by a word line WL that determines whether SRAM cell 10 is selected or not. A latch formed of pull-up transistors PU1 and PU2 and pull-down transistors PD1 and PD2 stores a bit, wherein the complementary values of the bit are stored in storage data nodes Q and QB. The stored bit can be written into, or read from, SRAM cell 10 through complementary bit lines including a bit line BLand a bit line bar BLB. SRAM cell 10 can be powered through a positive power supply node CVdd that can have a positive power supply voltage. SRAM cell 10 can be also connected to a power supply voltage node CVss, which may be an electrical ground. The transistors PU1 and PD1 form a first inverter INV1. Transistors PU2 and PD2 form a second inverter INV2. The first and second inverters INV1 and INV2 are cross-latched. For example, the input of the first inverter INV1 (e.g., gates of the transistors PU1 and PD1) is connected to the output of the second inverter INV2 (e.g., drains of the transistors PU2 and PD2), and the output of the first inverter INV1 (e.g., drains of the transistors PU1 and PD1) is connected to the input of the second inverter INV2 (e.g., gates of the transistors PU2 and PD2). The input of the first inverter INV1 is also connected to the transistor PG2. The output of the first inverter is also connected to the transistor PG1.

The sources of pull-up transistors PU1 and PU2 can be connected to positive power supply node CVdd. The sources of pull-down transistors PD1 and PD2 can be connected to the power supply voltage node CVss. The gates of transistors PU1 and PD1 can be connected to the drains of transistors PU2 and PD2, which can form a connection node that can be referred to as a storage data node QB. The gates of transistors PU2 and PD2 can be connected to the drains of transistors PU1 and PD1, which can form a connection node is referred to as a storage data node Q. A source/drain region of pass-gate transistor PG1 is connected to the bit line BL. A source/drain region of pass-gate transistor PG2 is connected to the bit line bar BLB.

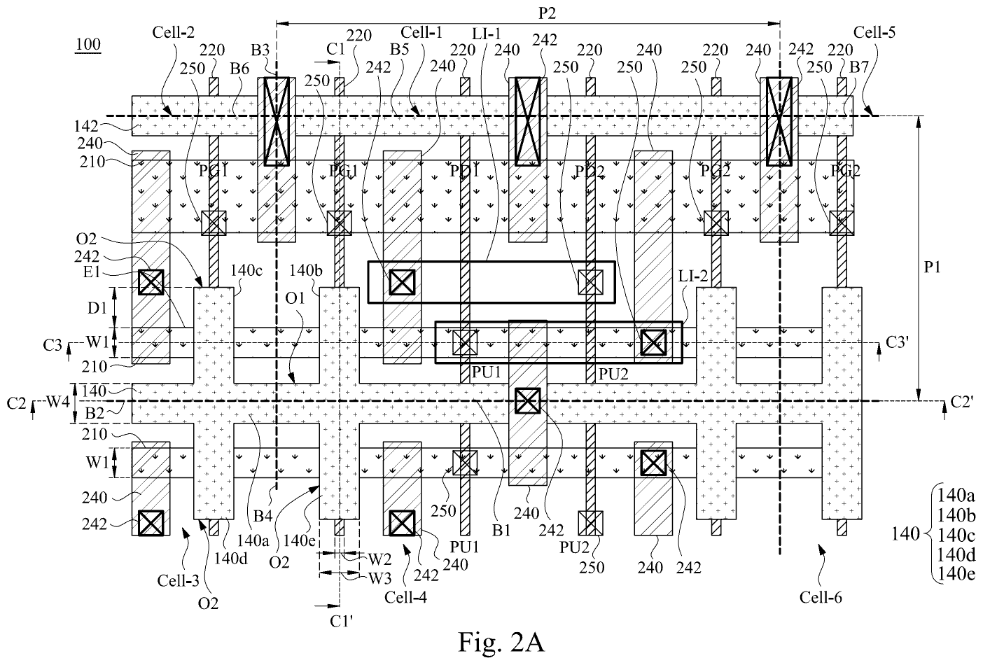

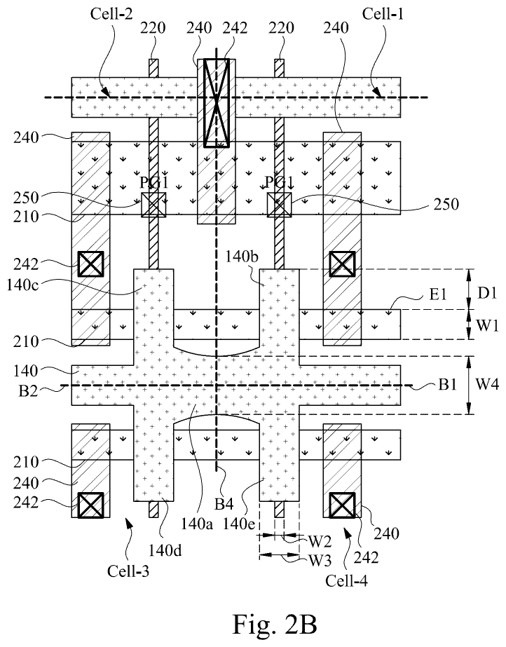

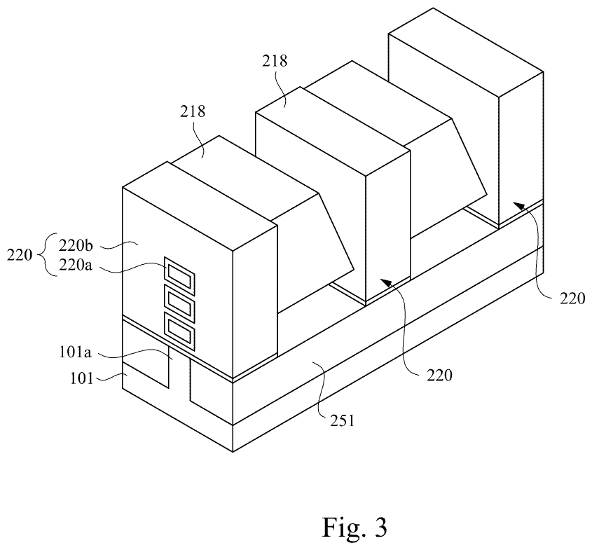

Reference is made to FIGS. 2A and 2B. FIG. 2A illustrates a cell array layout diagram of a semiconductor structure 100 of a SRAM circuit including SRAM cells Cell-1, Cell-2, Cell-3, Cell-4, Cell-5, and Cell-6 in accordance with some embodiments of the present disclosure. FIG. 2B is a local enlarged view of a region in FIG. 2A in accordance with some embodiments of the present disclosure. In some embodiments, the SRAM cells Cell-1, Cell-2, Cell-3, Cell-4, Cell-5, and Cell-6 can be similarly to each other. In FIG. 2A, the SRAM cell Cell-1 can form a rectangular cell shape to have an X-pitch P2 (or cell dimension in word-line routing direction) and a Y-pitch P1 (or cell dimension in bit-line routing direction). In a cell X-pitch direction, the SRAM cell Cell-1 may have to two channel layers extending in the bit-line routing direction to have highly capability for cell scaling. In some embodiments, the channel layers can be interchangeably referred to channel patterns, OD lines, or active regions.

In some embodiments, the SRAM cell Cell-1 can be a six-transistor (6T) SRAM cell to have six transistors formed upon (i.e., transistor PU1, transistor PU2, transistors PD1, transistor PD2, transistor PG1, transistor PG2). Specifically, the SRAM cell Cell-1 can include at least two pass-gate devices (e.g., transistors PG1 and PG2), at least two pull-down devices (e.g. transistors PD1 and PD2), and at least two pull-up devices (e.g., transistors PU1 and PU2). The SRAM cell Cell-1 can includes two cross coupled inverters including four transistors PD1, PU1, PD2, PU2 and further includes two transistors PG1 and PG2. In some embodiments, the transistors PG1, PG2, PD1, PD2, PU1, and PU2 may be MOS transistors with silicon channel layers. By way of example and not limitation, the transistors PG1, PG2, PD1, PD2, PU1, and PU2 can be all formed by either FinFET transistor or vertically stacked gate-all-around (VS-GAA) horizontal nanosheets transistors. Said FinFET transistor can be single-fin, or multiple fin, or combination. Said VS-GAA can be single channel, or multiple vertically stacked nano-sheet (or nano-wire), or combination.

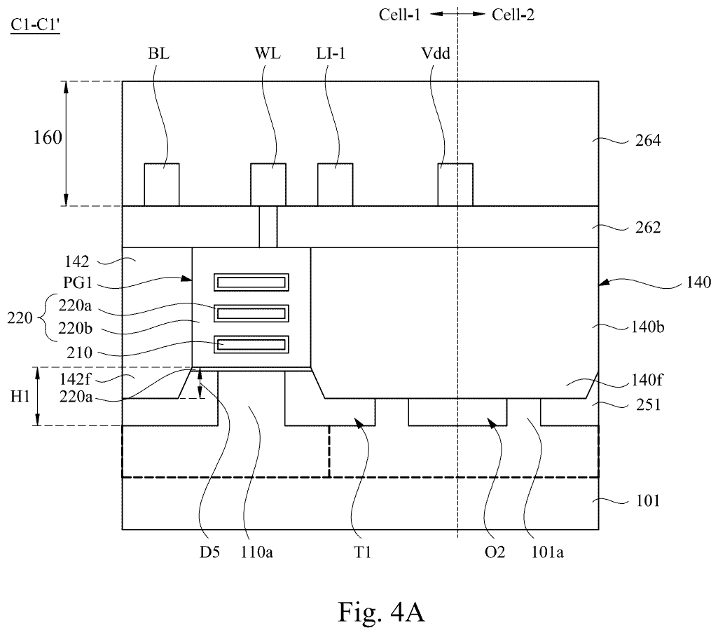

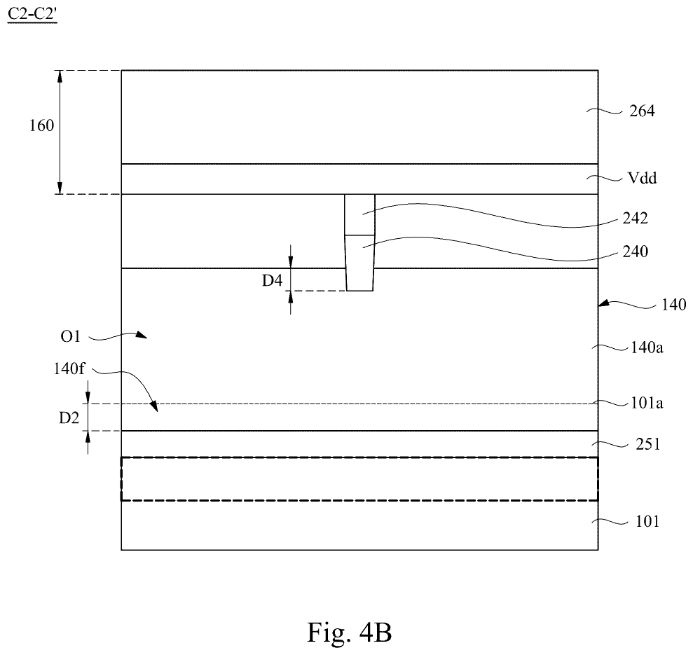

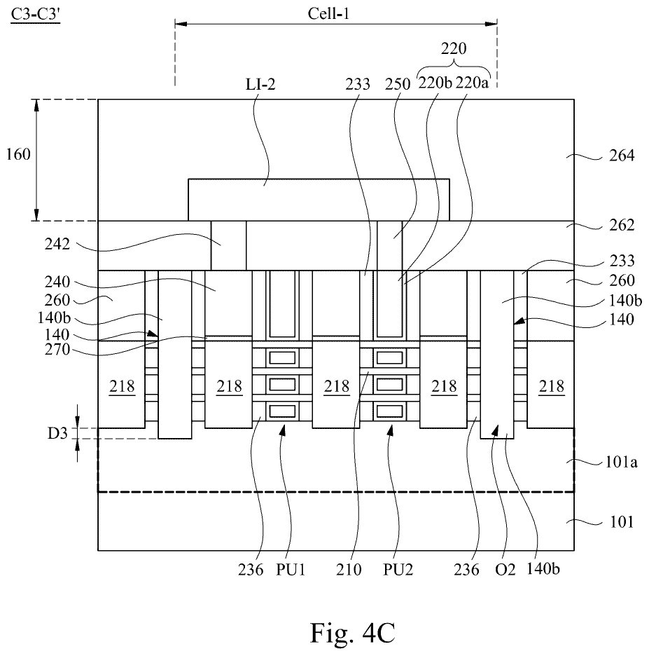

In FIG. 2A, the silicon channel layers of the transistors PG1, PG2, PD1, PD2, PU1, and PU2 may be formed by channel layers 210 wrapped by the gate structure 220. The channel layers 210 each can be semiconductor sheets stacked along the Z-direction (not shown) and, and the Z-direction is perpendicular to the plane formed by the X-direction and Y-direction, and the gate structure 220 can extend in the Y-direction. The gate structure 220 can be connected to an overlying level (e.g., word-line as shown in FIG. 4A) through a gate via 250. In some embodiments, the gate structure 220 can be interchangeably referred to a gate, a gate pattern, a gate strip, a gate segment, a gate layer, a metal gate, or a functional gate.

In some embodiments, in the configuration of SRAM with a 4CPP gate pitch, a cut metal gate (CMG) structure 140 can be implemented with an H-shape top view profile. The CMG structure 140 can be placed at the boundary of the SRAM cells rather than between adjacent channel regions 210 within the cells. Positioning the CMG structure 140 at the cell boundary can enable the structural shrinkage that would occur if the CMG were placed inside the SRAM cell between channel regions. Shrinkage in this setups often may lead to a reduced channel pitch, which in turn results in a smaller photoresist pattern on the substrate 101. This smaller pattern is more susceptible to peeling, which can increase the likelihood of manufacturing failures such as cut fails. Therefore, by relocating the CMG structure to the periphery of the SRAM cells, the SRAM can maintain a more robust and stable channel pitch, lowering the risk of peeling and cut failures. This approach not only enhances the manufacturing process by improving yield and reliability but also leverages the structural benefits of the CMG's H-shape, which optimizes the gate's functional performance in the memory cell's architecture.

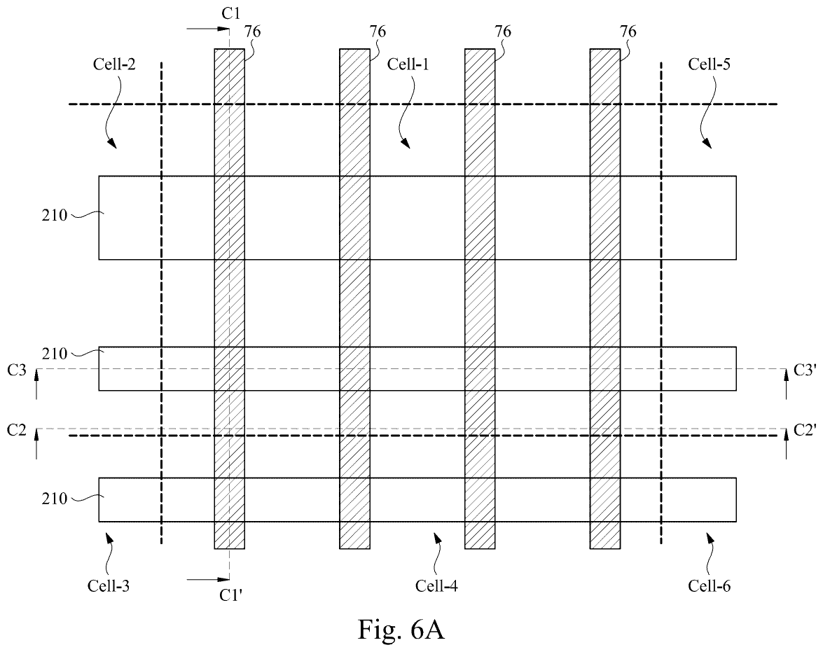

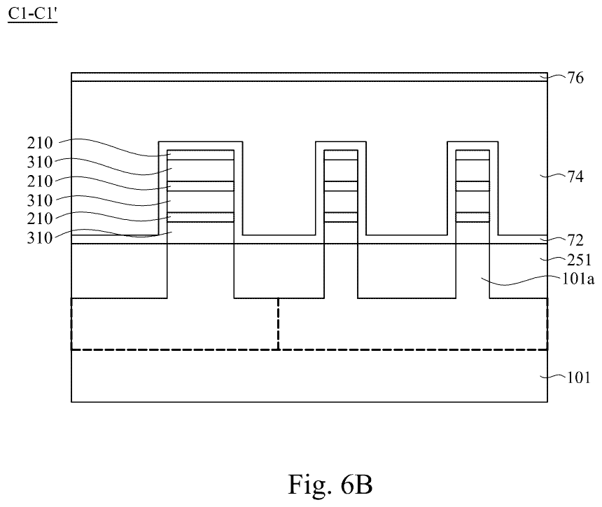

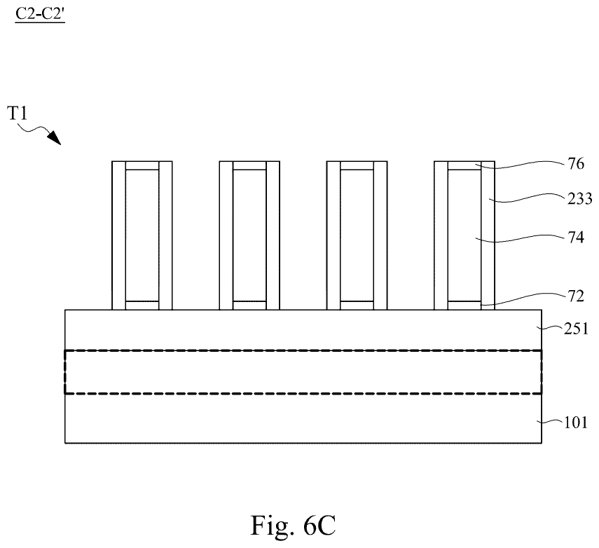

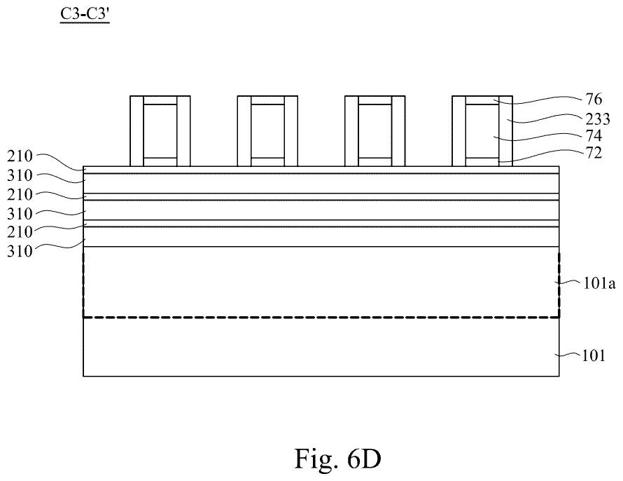

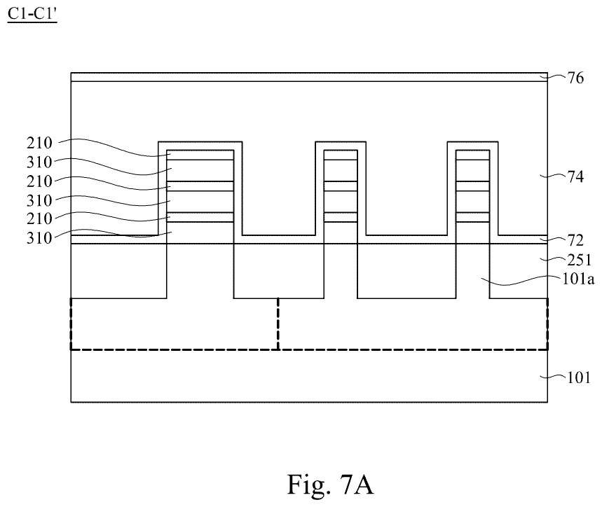

In some embodiments, the CMG structure 140 can include several segments (e.g., the second portion 140b, the third portion 140c, the fourth portion 140d, and the fifth portion 140e), which can replace the continuous poly on oxide definition (CPODE) pattern used in logic circuits and SRAM layouts. By integrating the CMG structure, the CPODE pattern can be omitted. This omission is because it prevents the CPD layout effect that may accompany the formation of the gate electrode layer. Such effects can be prevalent when using processes that form the CPODE pattern prior to gate electrode formation. The replacement gate (RPG) process can build the gate electrode layer 220b (see FIGS. 4A and 4C) for both pass-gate transistors PG1 and PG2 and pull-down transistors PD1 and PD2. This is facilitated by retaining the dummy gate structure (e.g., dummy dielectrics 72 and dummy gates 74 as shown in FIGS. 6A-6D) within the SRAM cells throughout the RPG process. The dummy gate structures are not removed beforehand but are instead replaced during the RPG. This method can reduce the differences in the pattern of the gate electrode layers between different types of transistors (e.g., the pull-down and pass-gate transistors). By maintaining uniformity in the gate electrode layer across different transistor types, the metal boundary effect (MBE), which can lead to variability in electrical characteristics and yield issues, can be minimized. Consequently, this approach not only streamlines the manufacturing process by eliminating a step but also enhances the overall reliability of the SRAM.

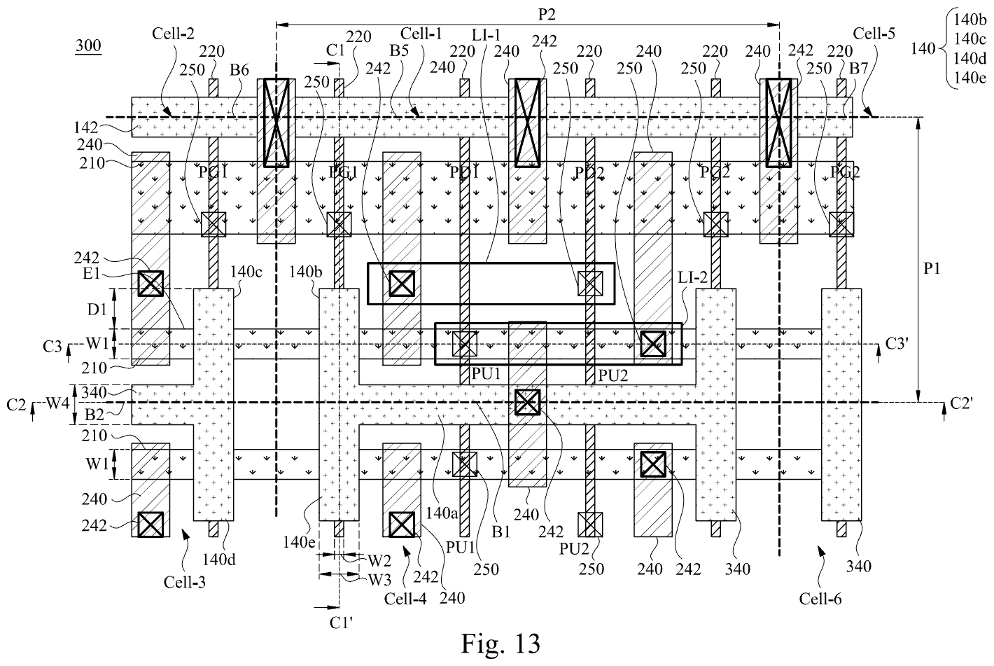

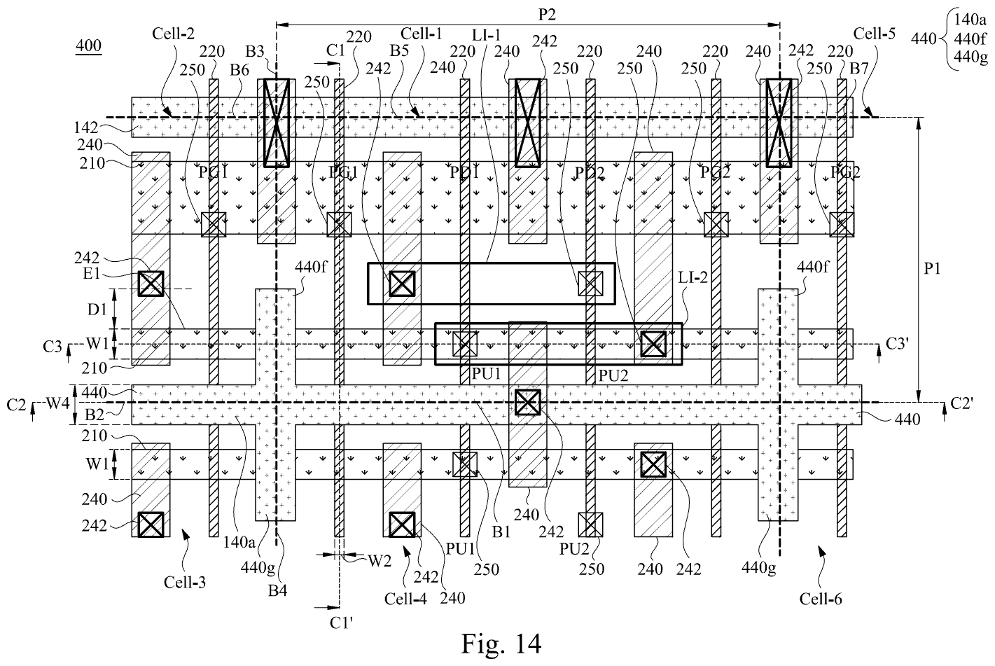

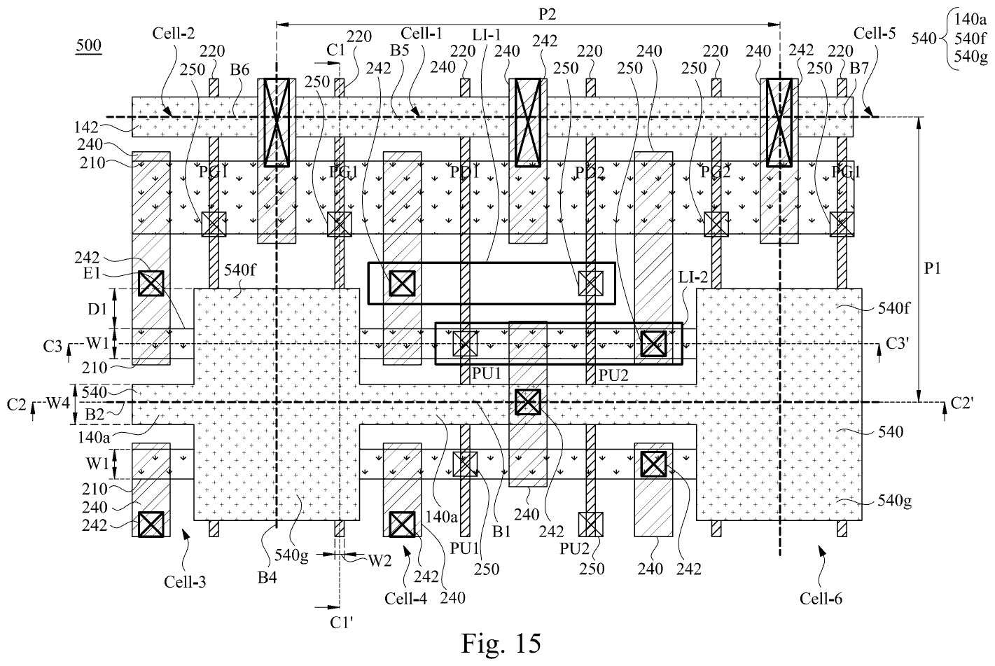

In some embodiments, the CMG structure 140 employed in the SRAM can provide a versatile approach to enhancing chip layout and functionality. The CMG structure 140 can be configured into multiple topographical profiles, such as H-shape (see FIGS. 2A), T-shape (see FIG. 13), cross-shape (see FIGS. 14 and 15), and square-shape (see FIG. 15), depending on the requirements and the layout of the SRAM cells. The ability of the CMG structure 140 to cut on the channel layer 210 can add further flexibility and precision in gate formation. For example, the H-shape profile of the CMG structure 140, as illustrated in FIG. 2A, can offer a detailed example of how the CMG integration impacts SRAM. The SRAM cells Cell-1 and Cell-4 can be arranged along a direction perpendicular to a lengthwise direction of the channel layer 210, and the SRAM cells Cell-2 and Cell-3 can be arranged along a direction perpendicular to the lengthwise direction of the channel layer 210. In other words, four adjacent SRAM cells, such as SRAM cells Cell-1, Cell-2, Cell-3, and Cell-4, can be organized into a 2×2 matrix with each cell placed in one of four quadrants. That is the SRAM cell Cell-1 can be placed in the first quadrant, the SRAM cell Cell-2 can be placed in the second quadrant, the SRAM cell Cell-3 can be placed in the third quadrant, and the SRAM cell Cell-4 can be placed in the fourth quadrant. Adjacent SRAM cells can display mirror symmetry at their boundaries.

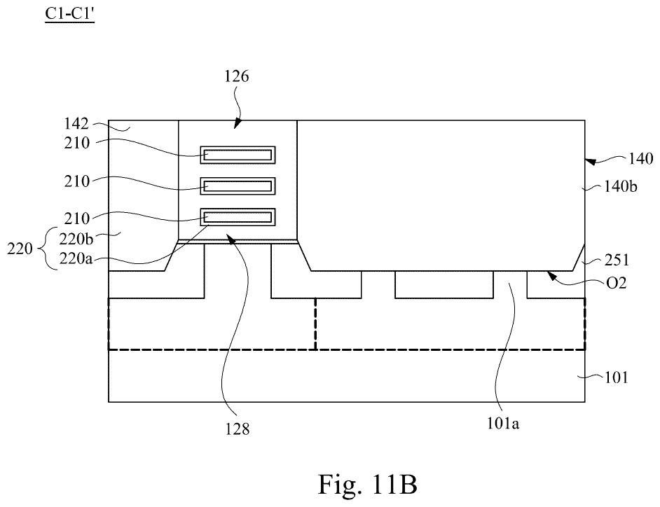

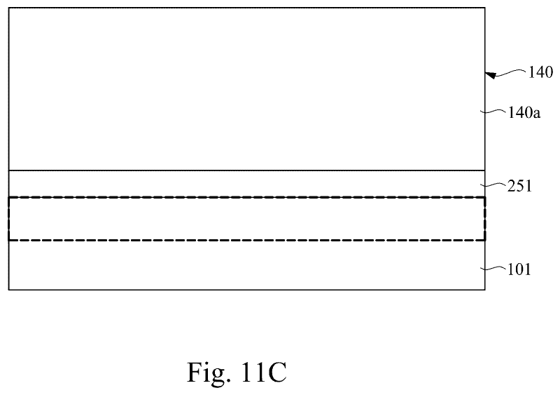

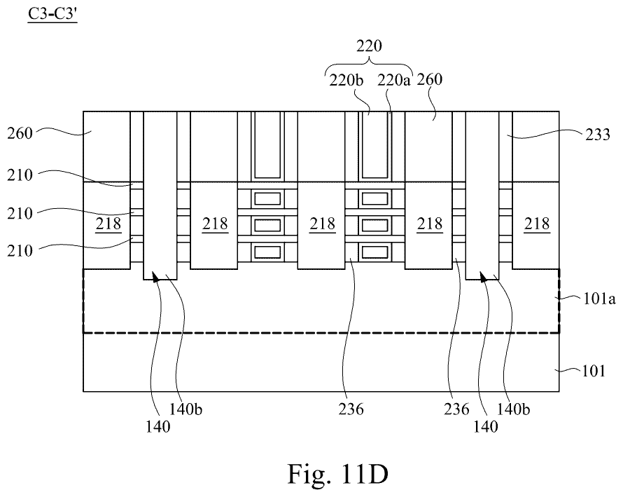

Post the RPG process, the CMG structure 140 can be crafted. Specifically, a continuous gate structure 220 can be first established on the substrate 101. Subsequently, the CMG process takes over, selectively removing parts of the continuous gate structure 220 and the underlying channel region 210. This selective etching can creates trenches O1 and O2 (see FIGS. 11B-11D) that are then filled with a dielectric material, forming the CMG. Specifically, wherein when viewed from above as shown in FIG. 2A, the first trench O1 can extend longitudinally along the channel region 210 and intersect the gate structures 220 within the SRAM cells Cell-1 and Cell-4, thereby severing the gate structures 220 within the SRAM cells Cell-1 and Cell-4. The second trench O2 can initiate from the first trench O1, take the place of a segment of the gate structures 220 within the SRAM cell Cell-1, and sever the channel region 210 originally beneath the segment of the gate structures 220 within the SRAM cell Cell-1.

The CMG structure 140 can include a primary portion or segment (e.g., first portion 140a) formed in the trench O1 and extending along the X-direction. Branching from the primary portion can be four additional segments (e.g., second portion 140b, third portion 140c, fourth portion 140d, fifth portion 140e), each formed in the trenches O2 and stretching out along the Y-direction, allowing the CMG structure 140 to achieve an H-shape profile when viewed from above, as depicted in FIG. 2A. The CMG structure 140 not only can differentiate and isolates the gate structure 220 and the channel region 210 within each SRAM cell but also enhance the electrical performance by reducing parasitic leakage and improving gate control. In some embodiments, the portions 140a through 140e can be interchangeably referred to as longitudinal portions.

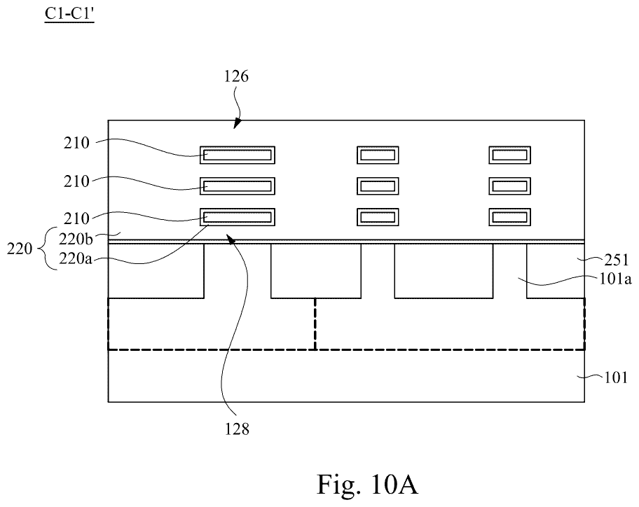

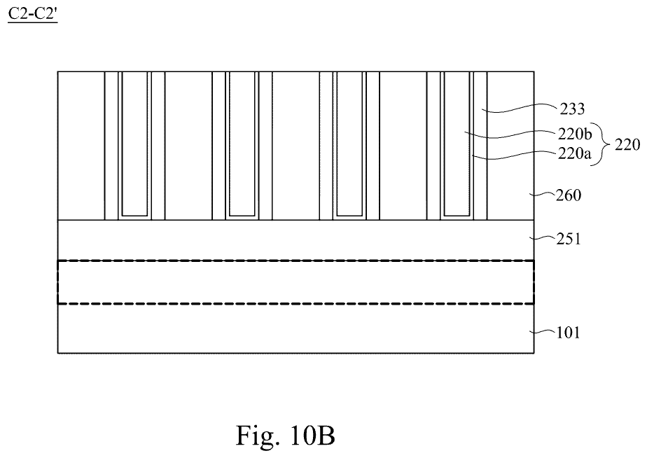

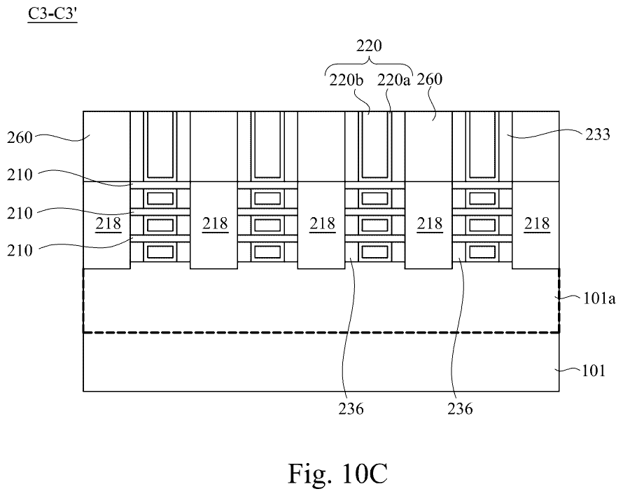

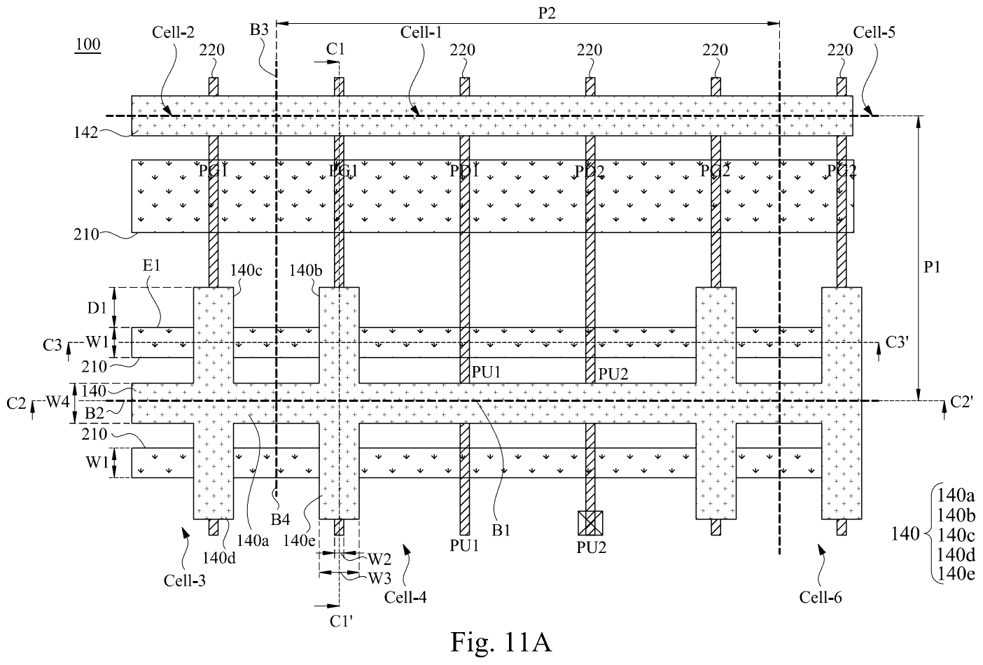

As shown in FIGS. 2A and 2B, the first portion 140a of the CMG structure 140 can define and isolate the memory cells. The first portion 140a of the CMG structure 140 can extend along the shared boundaries between SRAM cells (e.g., along boundary B1 between the SRAM cells Cell-1 and Cell-4, and boundary B2 between the SRAM cells Cell-2 and Cell-3), which in turn segments and separates the gate structures 220 within each of these SRAM cells, ensuring that each SRAM cell operates independently without electrical interference from its neighbors. The formation of the CMG structure 140 of the CMG structure involves a removal process. As the first portion 140a of the CMG structure 140 is formed along the X-direction, not only is the gate structure 220 removed, but also the gate spacers 233 (see FIGS. 10B and 11C) that are located on either side of this gate structure 220.

The removal of gate spacers 233 can allow the first portion 140a of the CMG structure 140 to extend continuously along the cell boundary for creating a uniform and seamless CMG structure 140 that spans across multiple cells, enhancing the integrity and operational isolation of the individual SRAM cells. On the other hand, the first portion 140a of the CMG structure 140 can extend along a direction perpendicular to the lengthwise direction of the gate structure 220 of the pass-gate transistor PG1 within the SRAM cell Cell-1 and interpose between the gate structure 220 of the pull-up transistor PU1 within the SRAM cell Cell-1 and the gate structure 220 of the second pull-up transistor within the SRAM cell Cell-4. The continuous extension of the first portion 140a of the CMG structure 140 along the cell boundary can minimize potential discontinuities in the gate structure 220, which could otherwise lead to leakage currents or other electrical anomalies.

As shown in FIG. 2B, the first portion 140a of the CMG structure 140 can present a round profile when viewed from above. The width W4 of the first portion 140a can vary along its length. In some embodiments, the width W4 of the first portion 140a can gradually increase as it approaches the intersections with the subsequent portions of the CMG structure 140 (e.g., the second portion 140b, the third portion 140c, the fourth portion 140d, and the fifth portion 140e). Conversely, the width W4 of the first portion 140a can gradually decrease as it extends away from these intersections. In some embodiments, the gradual widening near intersections provides increased structural support where the CMG structure branches out for maintaining the physical integrity under thermal and electronic stresses experienced during device operation. In some embodiments, the first portion 140a does not host any source/drain contacts 240, ensuring that its variable width and rounded profile do not interfere with the placement or formation of the source/drain contacts 240.

As shown in FIGS. 2A and 2B, the second, third, fourth, and fifth portions 140b, 140c, 140d, and 140e of the CMG structure 140 can define the operation and structural integrity of the SRAM cells. The second, third, fourth, and fifth portions 140b, 140c, 140d, and 140e of the CMG structure 140 can extend from the first portion 140a of the CMG structure 140 and can be positioned within individual SRAM cells. In other words, each segment (e.g., portions 140b, 140c, 140d, and 140e) can be associated with a specific SRAM cell (e.g., SRAM cells Cell-1, Cell-2, Cell-3, and Cell-4) respectively. The second, third, fourth, and fifth portions 140b, 140c, 140d, and 140e can replace portions of the existing gate structures 220 and cut off and isolate the corresponding channel regions 210 within each SRAM cell. This modification can enhance SRAM cell performance by preventing electrical interference between adjacent SRAM cells.

After severing the channel regions 210, the portions 140b through 140e of the CMG structure 140 can extend beyond the edge of these regions by at least half the width W1 of the channel regions 210, ensuring that no metal residue remain that could potentially cause short-circuiting or other electrical failures. By way of example and not limitation, the second portion 140b of the CMG structure 140 not only can cut off the channel region 210 in SRAM cell Cell-1 but also extend beyond the edge E1 of the channel region 210 by a dimension D1 that is greater than half of the width W1, in a range from about 5 to 10 nm, such as about 5, 6, 7, 8, 9, or 10 nm. In some embodiments, the portions 140b through 140e of the CMG structure 140 can be in contact with corresponding longitudinal ends of the gate structures 220.

In some embodiments, during the formation of the portions 140b through 140e of the CMG structure 140, when the gate structures 220 are removed, the gate spacers 233 adjacent to these structures are also partially removed, which in turn reduces the width of the gate spacers but also allows the CMG segments to be formed wider than the original occupied gate structures 220. The resultant portions 140b through 140e of the CMG structure 140 can be formed with a width W3 that is greater than the width W2 of the original gate structures W2. By isolating channel regions 210 and adjusting structural dimensions, the CMG structure 140 can help in minimizing semiconductor device issues, such as cross-talk and electrical leakage, thereby enhancing the overall efficiency of the memory device. In some embodiments, the width W3 of one of the portions 140b through 140e of the CMG structure 140 can be narrower than the width W4 of the portion 140a of the CMG structure 140.

In some embodiments, the second portion 140b, the third portion 140c, the fourth portion 140d, and the fifth portion 140e of the CMG structure 140 can be widen along the X-direction to selectively replace at least part or all of the adjacent source/drain regions 218 (see FIG. 15). By way of example and not limitation, the second portion 140b can widen towards the third portion 140c, eventually merging into an integrated structure, ensuring that the source/drain region 218, which originally lies between these two portions, can be fully encompassed and replaced by the CMG structure 140. Similarly, the fourth portion 140d of the CMG structure 140 can widen towards the fifth portion 140e, eventually merging into an integrated structure, ensuring that the source/drain region 218, which originally lies between these two portions, can be fully encompassed and replaced by the CMG structure 140, thereby streamlining the structural design and improving the electrical characteristics of the memory cell. By widening the CMG structure 140 and integrating adjacent portions of the CMG structure 140, which in turn reduces the likelihood of electrical leakage between neighboring source/drain regions.

In some embodiments, a CMG structure 142 can be formed nearby transistors, such as the pass-gate transistors PG1 and PG2, and the pull-down transistors PD1 and PD2, enhancing the functional isolation and integration of nearby transistors. In some embodiments, the CMG structure 142 can have a strip-like profile that extends along specified boundaries within the SRAM cell array. This linear configuration can act as a gate-cut structure, facilitating precise isolation and separation of the gate structures 220, thereby enhancing electrical isolation and reducing leakage currents between the transistors of adjoining SRAM cells. The CMG structure 142 can extend boundaries B5, BB6, and B7 of the SRAM cells Cell-1, Cell-2. In some embodiments, the source/drain contact 240 can be placed to span across the CMG structure 142. Positioned above the common source/drain region 218 shared by the pull-down transistors PD1 and PD2, the source/drain contact arrangement can ensures that, despite the CMG structure 142 beneath, connectivity and electrical flow within the source/drain regions 218 can be uninterrupted.

In some embodiments, the CMG structures 140 and 142 can be interchangeable referred to as or an isolation structure. In some embodiments, the CMG structure 140/142 can be interchangeably referred to a dielectric line, an isolation structure, a gate end dielectric line, a gate end dielectric strip, a gate end dielectric pattern, a gate isolation, an isolation structure an isolation strip, a dielectric strip, or a dielectric region. In some embodiments, the semiconductor structure including the CMG structure 140/142 can incorporate a diverse range of transistor technologies to enhance performance and scalability. It can include both silicon (Si) and silicon-germanium (SiGe) in planar configurations. The semiconductor structure including the CMG structure 140/142 also can integrate FinFETs. Moreover, the semiconductor structure including the CMG structure 140/142 can integrate Gate-All-Around (GAA) technology and nanosheet transistors. Forksheet and Complementary FET (CFET) structures can be also included.

In FIG. 2A, the transistors PU1 and PD1 may share a first one of the gate structures 220, and the transistors PU2 and PD2 may share a second one of the gate structures 220. In the SRAM cell Cell-1, the transistors PU1 and PU2 may be formed on a first one of the channel layers 210, the transistors PG1, PG2, PD1, and PD2 may be formed on a second one of the channel layers 210. The source nodes of the transistor PD1 and the transistor PD2 can share a first one of source/drain contact 240 and electrically connected to a power supply voltage line Vss through the source/drain via 242. The drain nodes of the transistor PU1 and the transistor PU2 can share a second one of the source/drain contact 240 and electrically connected to a power supply voltage line Vdd through the source/drain via via-0. The semiconductor structure further includes source/drain regions 218 (see FIG. 4C) below the source/drain contacts 240 and between the gate structures 220.

In some embodiments, the layouts as shown in FIGS. 2A and 2B are represented by a plurality of masks generated by one or more processors and/or stored in one or more non-transitory computer-readable media. Other formats for representing the layout are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

Reference is made to FIGS. 3-4C. FIG. 3 illustrates a perspective view of an example nano-FET device in accordance with some embodiments of the present disclosure. FIGS. 4A-4C illustrate schematic cross-sectional views obtained from reference cross-section C1-C1′, C2-C2′, and C3-C3′ in FIG. 2A, respectively. In some embodiments, the nano-FET may be nanosheet field-effect transistors (NSFETs), nanowire field-effect transistors (NWFETs), gate-all-around field-effect transistors (GAAFETs), or the like. In some embodiments, the transistor shown in FIG. 3 can include the channel regions 210, the source/drain regions 218 on opposite sides of the channel regions 210, and the gate structure 220 wrapping around the channel regions 210.

Specifically, as shown in FIGS. 4A-4C, the substrate 101 is provided for forming nano-FETs. The substrate 101 may be a semiconductor substrate, such as a bulk semiconductor, a semiconductor-on-insulator (SOI) substrate, or the like, which may be doped (e.g., with a p-type or an n-type impurity) or undoped. The substrate 101 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the substrate 101 may be a material, such as a III-V compound semiconductor, a II-VI compound semiconductor, or the like. In some embodiments, the semiconductor material of the substrate 101 may include silicon; germanium; a compound semiconductor including silicon carbide, gallium arsenide, gallium stannum, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 101 may be lightly doped with a p-type or an n-type impurity to form a first conductivity type well region 100a and a second conductivity type well region 100b having an opposite conductivity type to the first conductivity type well region. An anti-punch-through (APT) implantation may be performed on an upper portion of the substrate 101 to form an APT region. During the APT implantation, impurities may be implanted in the substrate 101. The impurities may have a conductivity type opposite from a conductivity type of source/drain regions that will be subsequently formed in each of the n-type region and the p-type region. The APT region may extend under the source/drain regions in the nano-FETs. The APT region may be used to reduce the leakage from the source/drain regions to the substrate 101. In some embodiments, the doping concentration in the APT region may be in the range of about 10¹⁸ cm⁻³ to about 10¹⁹ cm⁻³. By way of example and not limitation, first conductivity type well region 100a can be a P-type well region, and the second conductivity type well region 100b can be an N-type well region. In some embodiments, the P-type well region can have n-type devices, such as NMOS transistors, formed thereon, and the N-type well region can have p-type devices, such as PMOS transistors, formed thereon.

Trenches T1 (see FIG. 4A) formed in the substrate 101 defining the fin strip 101a (see FIGS. 4A and 4C). In the other words, the fin strip 101a is semiconductor strip patterned in the substrate 101. A shallow trench isolation (STI) structure 251 (see FIGS. 4A and 4B) can be formed over the substrate 101 and laterally surround the fin strip 101a. In some embodiments, the top surface of the STI structure 251 is coplanar (within process variations) with a top surface of the fin strip 101a. In some embodiments, the top surface of the STI structure 251 is above or below the top surface of the fin strip 101a. In some embodiments, the STI structure 251 may separate the features of adjacent devices.

The channel layers 210 (see FIGS. 4A and 4C) are stacked along the Z-direction over the fin strip 101a and act as active regions. In some embodiments, the channel regions 210 may include p-type nanostructures, n-type nanostructures, or a combination thereof and extend along an X-direction. For example, the channel layer 210 can be a silicon sheet that forms a silicon channel layer for the corresponding transistor. In some embodiments, channel layer 210 may have a width in a range from about 4 nm to about 7 nm when viewed in X-direction. In some embodiments, the number of stacked channel layers 210 may be between about 2 to about 10. In some embodiments, the thickness of the channel layer 210 may be within a range about 3 nm to about 10 nm. In some embodiments, the channel regions 210 can be interchangeably referred to as channel patterns, nanostructures, nanosheets, semiconductor sheets, or nanowires.

The gate structures 220 (see FIGS. 4A and 4C) may include one or more gate electrode layer 220b and a gate dielectric layer 220a. The gate dielectric layers 220a can be formed over top surfaces of the fin strip 101a and along top surfaces, sidewalls, and bottom surfaces of the channel regions 210. The gate electrode layers 210b are formed over the gate dielectric layer 220a. In some embodiments, the gate electrode layer 220b may be made of conductive material, such as aluminum (Al), copper (Cu), tungsten (W), titanium (Ti), tantalum (Ta), or other applicable materials. In some embodiments, the gate electrode layer 220b may include multiple material structure selected from a group consisting of poly gate/SiON structure, metals/high-K dielectric structure, Al/refractory metals/high-K dielectric structure, silicide/high-K dielectric structure, or combination. In some embodiments, the gate electrode layers 210b may include one or more work-function layers (not shown). In some embodiments, the work function layer can be made of metal material, and the metal material may include N-work-function metal or P-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal may include titanium nitride (TiN), tungsten nitride (WN), tantalum nitride (TaN), ruthenium (Ru) or a combination thereof. In some embodiments, the gate electrode layer 220b is formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

In some embodiments, the gate dielectric layer 220a can be made of silicon oxide (SiOₓ), silicon nitride (SiₓN_{y}), silicon oxynitride (SiON), dielectric material(s) with high dielectric constant (high-k), or a combination thereof. The high dielectric constant (high-k) material may be hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. In some embodiments, the gate dielectric layer 220a includes Lanthanum (La) dopant. In some embodiments, the gate dielectric layer 220a can be deposited by a plasma enhanced chemical vapor deposition (PECVD) process or by a spin coating process.

The source/drain regions 218 (see FIG. 4C) may include silicon with boron (e.g., B₁₁) content. In some embodiments, the source/drain regions 218 can be formed by epitaxially growing boron in Si material. In some embodiments, the source/drain regions 218 may include materials and/or dopants that achieve desired tensile stress and/or compressive stress in the channel layer 210. In some embodiments, the source/drain regions 218 can be interchangeably referred to epitaxial structures, source/drain structures, or source/drain patterns. In some embodiments, a bottom of the source/drain regions 218 can be in contact with the well region. In some embodiments, a dielectric layer can be formed to sandwich between the source/drain region 218 and the well region.

Gate spacers 233 (see FIG. 4C) can be formed on the sidewalls of the gate structure 220. In some embodiments, the gate spacer 233 may be made of SiO₂, Si₃N₄, SiON, SiOC, SiOCN base dielectric material, air gap, or combinations thereof. In some embodiments, the gate spacer 233 may be made of a low-dielectric constant (low-k) materials having a k-value less than about 3.5, may be utilized. In some embodiments, the gate spacers 233 can be constructed from multiple layers to enhance device performance and reliability. Inner spacers 236 (see FIG. 4C) may be formed between the source/drain regions 218 and the gate structure 220 and act as isolation features. In some embodiments, the inner spacers 236 can be interchangeably referred to lower gate spacers. In some embodiments, the inner spacers 236 may have a lateral dimension in a range from about 4 nm to about 12 nm.

The CMG structure 140 (see FIGS. 4A-4C) can include the portions 140a through 140e. In some embodiments, the portion 140a of the CMG structure 140 can act as a gate-cut structure for the gate structure 220. In some embodiments, the portion 140a of the CMG structure 140 can be placed at the edges of cells, adjacent to the pull-up transistors PU1 and PU2. In some embodiments, the portion 140a of the CMG structure 140 can span the entire X-pitch P2 (see FIG. 2A) of the SRAM cell along the bit-line routing direction. The portion 140a of the CMG structure 140 can mitigate the bridging of epitaxial growth across different source/drain regions 218, thus allowing for the maximization of the size of the source/drain region 218 to abut and halt at the portion 140a of the CMG structure 140. Enlarging the source/drain regions 218 can not only lower their resistance but also facilitate the incorporation of strain layers, such as SiGe for PMOSFETs, enhancing carrier mobility due to the increased volume of the source/drain region 218. Therefore, the source/drain region 218 can be in contact with the portion 140a of the CMG structure 140 and the longitudinal end of the gate structure 220.

In some embodiments, the portion 140a (see FIGS. 2A, 4A, and 4B) of the CMG structure 140 can have a lower portion 140f embedded in the STI structure 251. In some embodiments, the lower portion 140f can downwardly extend beyond the top surface of the fin strip 101a by at least half the height H1 (see FIG. 4A) of the fin strip 101a. In some embodiments, the lower portion 140f can downwardly extend beyond the top surface of the fin strip 101a by less than half the height H1 of the fin strip 101a. In the other words, the lower portion 140f (see FIG. 4B) of the portion 140a can be embedded in the STI structure 251 and having a vertical dimension D2 (see FIG. 4B) in a range from about 5-150 nm, such as about 5, 10, 20, 30, 40, 50, 60, 70, 80, 90, 100, 110, 120, 130, 140, or 150 nm.

In some embodiments, the portions 140b through 140e (see FIGS. 2A, 4A, and 4C) of the CMG structure 140 can be formed to replace with some gate structures 220. In SRAM designs, it can implement channel layer cuts (or in the oxide definition (OD)) at the drain-node ends of pull-up transistors PU1 and PU2 to isolate adjacent cells. In some embodiments, the portions 140b through 140e can form an isolation region separating the source/drain regions of neighboring semiconductor devices from each other, and thus the different semiconductor devices can be separated. In some embodiments, the portions 140b through 140e, placed between the gate spacer 233, can interrupt the channel layer 210 at a depth surpassing the bottom of adjacent source/drain regions 218. In some embodiments, the dielectric gate 230 can downwardly extend deeper than the top surface of the fin strip 101a by about a vertical dimension D3. By way of example and not limitation, the vertical dimension D3 can be in a range from about 5 to 150 nm, s such as about 5, 10, 20, 30, 40, 50, 60, 70, 80, 90, 100, 110, 120, 130, 140, or 150 nm.

In some embodiments, the CMG structure 142 (see FIGS. 2A and 4A) can act as a gate-cut structure for the gate structure 220. In some embodiments, the CMG structure 142 can be placed at the edges of cells, adjacent to the pass-gate transistors PG1 and PG2, and the pull-down transistors PD1 and PD2. In some embodiments, the CMG structure 142 can span the entire X-pitch P2 (see FIG. 2A) of the SRAM cell along the bit-line routing direction. The CMG structure 142 can mitigate the bridging of epitaxial growth across different source/drain regions 218, thus allowing for the maximization of the size of the source/drain region 218 to abut and halt at the CMG structure 142. Enlarging the source/drain regions 218 can not only lower their resistance but also facilitate the incorporation of strain layers, such as SiGe for PMOSFETs, enhancing carrier mobility due to the increased volume of the source/drain region 218. Therefore, the source/drain region 218 can be in contact with the CMG structure 142 and the longitudinal end of the gate structure 220.

In some embodiments, the CMG structure 142 (see FIG. 4A) can have a lower portion 142f embedded in the STI structure 251. In some embodiments, the lower portion 142f can downwardly extend beyond the top surface of the fin strip 101a by at least half the height H1 (see FIG. 4A) of the fin strip 101a. In some embodiments, the lower portion 142f can downwardly extend beyond the top surface of the fin strip 101a by less than half the height H1 of the fin strip 101a. In the other words, the lower portion 142f (see FIG. 4A) of the portion 140a can be embedded in the STI structure 251 and having a vertical dimension D5 (see FIG. 4B) in a range from about 5-150 nm, such as about 5, 10, 20, 30, 40, 50, 60, 70, 80, 90, 100, 110, 120, 130, 140, or 150 nm.

In some embodiments, the CMG structure 140/142 can include a single layer or multiple layers of different dielectric materials. In some embodiments, the bottom end of the CMG structure 140/142 can have a narrower width than a top end of the CMG structure 140/142. In some embodiments, the material of the CMG structure 140/142 is different from the material of the gate structures 220. By way of example and not limitation, the CMG structure 140/142 may be formed of or comprise SiO₂, SiCO, SiO2:F, SiN, SiCN, SiOCN, oxide, nitrogen, the like, or combinations thereof. In some embodiments, the CMG structure 140/142 may be made of a nitride-based material, such as Si₃N₄, or a carbon-based material, such as SiOCN, or combinations thereof. In some embodiments, the CMG structure 140/142 may be made of a metal oxide material. In some embodiments, the CMG structure 140/142 may be made of a material having a dielectric constant greater than about 9 (e.g., high dielectric constant (high-k) material). For example, the CMG structure 140/142 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The CMG structure 140 may be formed of a homogenous material, or may have a composite structure including more than one layer. In some embodiments, the CMG structure 140/142 may include dielectric liners, which may be formed of, for example, silicon oxide or a high-k dielectric material.

An inter-layer dielectric (ILD) layer 260 (see FIG. 4C) can be formed between the gate structures 220 and over the source/drain regions 218, and an ILD layer 262 (see FIGS. 4A-4C) can be formed over the ILD layer 260. The source/drain contacts 240 (see FIGS. 4B and 4C) can be formed in the ILD layer 260 and over the source/drain regions 218. In some embodiments, a source/drain silicide region 270 can be formed to sandwich between the source/drain region 218 and the source/drain contact 240. In some embodiments, the source/drain vias 242 (see FIGS. 4B and 4C) can be formed in the ILD layer 262 to land on the source/drain contacts 240. In some embodiments, the gate vias 250 (see FIGS. 4A and 4C) can be formed to pass through the ILD layer 262 and land on the corresponding gate structures 220. In some embodiments, as shown in FIGS. 2A and 4B, the source/drain contact 240 (see FIG. 4B) landing on the epitaxial source/drain region 218 between the pull-up transistors PU1 and PU2 can laterally extend to overlap the first portion 140a of the CMG structure 140 and further downwardly extend into the first portion 140a of the CMG structure 140 in a vertical dimension D4 (see FIG. 4B). By way of example and not limitation, the vertical dimension D4 can be in a range from about 3 to 50 nm, such as about 3, 5, 10, 15, 20, 25, 30, 35, 40, 45, or 50 nm. In some embodiments, as shown in FIG. 2A, the source/drain contact 240 (see FIG. 2A) landing on the epitaxial source/drain region 218 between the pull-down transistors PD1 and PD2 can laterally extend to overlap the CMG structure 142 and further downwardly extend into the CMG structure 142 as the CMG structure 142 shown in FIG. 4B.

An interconnect structure 160 including metal lines and vias can be formed in the IMD layer 264 formed over the ILD layer 262 to electrically connect to the corresponding gate vias 250 or the corresponding source/drain vias 242. The metal lines can include the power supply voltage lines Vdd, the local connection line LI-1, the bit-line BL, and the word-line WL. The IMD layer 264 may provide electrical insulation as well as structural support for the various features of the interconnect structure.

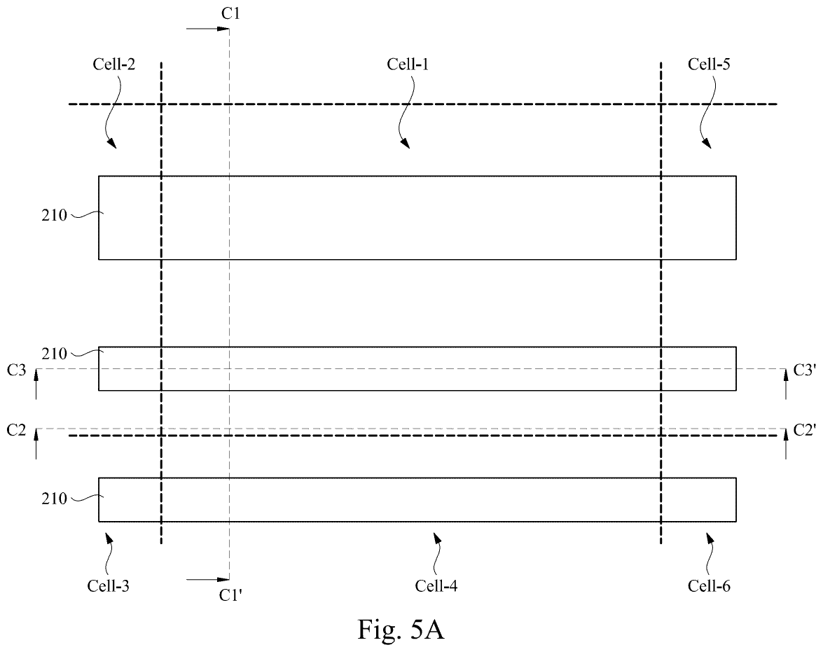

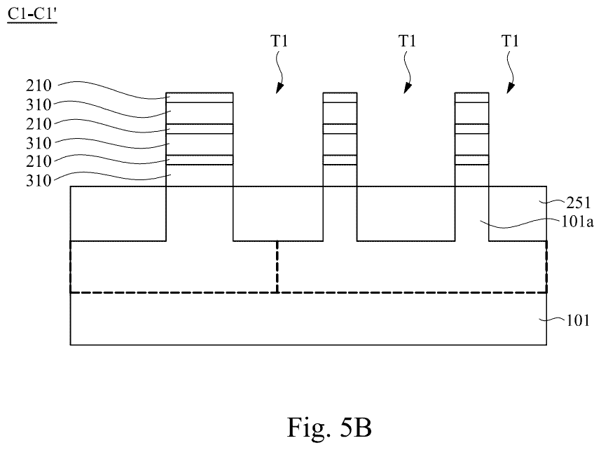

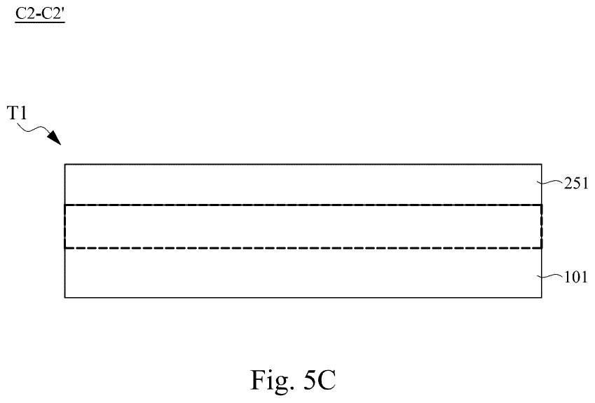

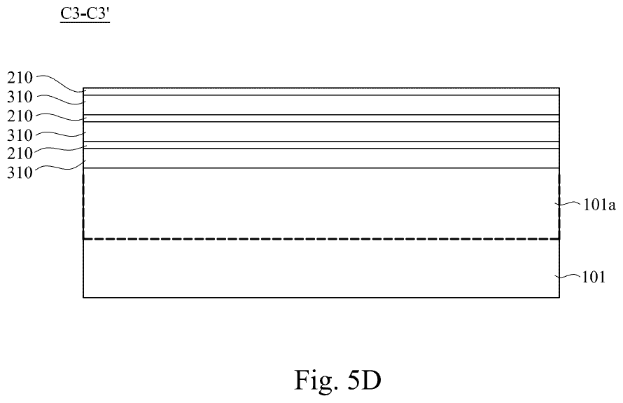

Reference is made to FIGS. 5A-12D. FIGS. 5A-12D illustrate schematic views of intermediate stages in the formation of a semiconductor structure in accordance with some embodiments. Specifically, FIGS. 5A, 6A, 11A, and 12A illustrate top views of the semiconductor structure corresponding in accordance with some embodiments. FIGS. 5B, 6B, 7A, 8A, 9A, 10A, 11B, and 12B illustrate cross-sectional views of intermediate stages obtained from the reference cross-section C1-C1′ in the formation of the semiconductor structure in accordance with some embodiments. FIGS. 5C, 6C, 7B, 8B, 9B, 10B, 11C, and 12C illustrate cross-sectional views of intermediate stages obtained from the reference cross-section C2-C2′ in the formation of the semiconductor structure in accordance with some embodiments. FIGS. 5D, 6D, 7C, 8C, 9C, 10C, 11D, and 12D illustrate cross-sectional views of intermediate stages obtained from the reference cross-section C3-C3′ in the formation of the semiconductor structure in accordance with some embodiments.

As with the other method embodiments and exemplary devices discussed herein, it is understood that parts of the semiconductor structure 100 may be fabricated by a CMOS technology process flow, and thus some processes are only briefly described herein. Further, the exemplary semiconductor structure 100 may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary semiconductor structure 100 can include a plurality of semiconductor devices (e.g., transistors), including PFETs, NFETs, etc., which may be interconnected. It is understood that additional operations can be provided before, during, and after the processes shown by FIGS. 5A-12D, and some of the operations described below can be replaced or eliminated, for additional embodiments of the method. The order of the operations/processes may be interchangeable.

Reference is made to FIGS. 5A-5D. A substrate 101 is provided for forming nano-FETs. In some embodiments, material and manufacturing method of the substrate 101 is substantially the same as that shown in FIGS. 4A-4C, and the related detailed descriptions may refer to the foregoing paragraphs, and are not described again herein for the purpose of simplicity and clarity. A multi-layer stack is formed over the substrate 101. The multi-layer stack can include alternating first semiconductor layers and second semiconductor layers. The first semiconductor layers formed of a first semiconductor material, and the second semiconductor layers can be formed of a second semiconductor material different than the first semiconductor material. The semiconductor materials may each be selected from the candidate semiconductor materials of the substrate 101. In some embodiments, the multi-layer stack includes two layers of each of the first semiconductor layers and the second semiconductor layers. It should be appreciated that the multi-layer stack may include any number of the first semiconductor layers and the second semiconductor layers.

In some embodiments, and as will be subsequently described in greater detail, the first semiconductor layers will be removed and the second semiconductor layers will patterned to form channel layers for the nano-FETs. The first semiconductor layers can be sacrificial layers (or dummy layers), which will be removed in subsequent processing to expose the top surfaces and the bottom surfaces of the second semiconductor layers. The first semiconductor material of the first semiconductor layers is a material that has a high etching selectivity from the etching of the second semiconductor layers, such as silicon germanium. The second semiconductor material of the second semiconductor layers is a material suitable for both n-type and p-type devices, such as silicon.

In embodiments, the first semiconductor material of the first semiconductor layers may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers in the multi-layer stack may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers) may be formed to be thinner than other layers (e.g., the first semiconductor layers).

Trenches T1 can be patterned in the substrate 101 and the multi-layer stack to form fin strips 101a, semiconductor sheets 310, and channel layers 210 (see FIGS. 5B and 5D). The fin strips 101a are semiconductor strips patterned in the substrate 101. The semiconductor sheets 310 and the channel layers 210 include the remaining portions of the first semiconductor layers and the second semiconductor layers, respectively. The trenches T1 may be patterned by any acceptable etch process, such as a reactive ion etch (RIE), neutral beam etch (NBE), the like, or a combination thereof. The etching may be anisotropic. The fin strips 101a, the semiconductor sheets 310, and the channel layers 210 may be patterned by any suitable method. For example, the fin strips 101a, the semiconductor sheets 310, and the channel layers 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

The STI structures 251 (see FIGS. 5B and 5C) can be formed over the substrate 101 and between adjacent fin strips 101a. The STI structures 251 can be disposed around at least a portion of the fin strips 101a such that at least a portion of the semiconductor sheet 310 and the channel layer 210 protrude from between adjacent STI structures 251. In some embodiments, the top surfaces of the STI structures 251 can be coplanar (within process variations) with the top surfaces of the fin strips 101a. The STI structures 251 may be formed by any suitable method. For example, an insulation material can be formed over the substrate 101 and the semiconductor sheets 310 and the channel layers 210, and between adjacent fin strips 101a. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In some embodiments, the insulation material is formed such that excess insulation material covers the semiconductor sheets 310 and the channel layers 210. Although the STI structures 251 are each illustrated as a single layer, some embodiments may utilize multiple layers. For example, in some embodiments a liner (not separately illustrated) may first be formed along surfaces of the substrate 101, the fin strips 101a, the semiconductor sheets 310, and the channel layers 210. Thereafter, a fill material, such as those previously described may be formed over the liner.

A removal process can be then applied to the insulation material to remove excess insulation material over the semiconductor sheets 310 and the channel layer 210. In some embodiments, a planarization process such as a chemical mechanical polish (CMP), an etch-back process, combinations thereof, or the like may be utilized. In embodiments in which a mask remains on the semiconductor sheets 310 and the channel layers 210, the planarization process may expose the mask or remove the mask. After the planarization process, the top surfaces of the insulation material and the mask (if present) or the semiconductor sheet 310/the channel layer 210 are coplanar (within process variations). Accordingly, the top surfaces of the mask (if present) or the semiconductor sheet 310/channel layer 210 can be exposed through the insulation material. In some embodiments, no mask remains on the semiconductor sheets 310 and the channel layers 210. The insulation material can be then recessed to form the STI structures 251. The insulation material is recessed, such as in a range from about 30 nm to about 80 nm, such that at least a portion of the semiconductor sheets 310 and the channel layers 210 can protrude from between adjacent portions of the insulation material. Further, the top surfaces of the STI structures 251 may have a flat surface as illustrated, a convex surface, a concave surface (such as dishing), or a combination thereof. The insulation material may be recessed using any acceptable etching process, such as one that is selective to the material of the insulation material (e.g., selectively etches the insulation material of the STI structures 251 at a faster rate than the materials of the fin strips 101a and the semiconductor sheets 310 and the channel layers 210). For example, an oxide removal may be performed using dilute hydrofluoric (dHF) acid.

Reference is made to FIGS. 6A-6D. A dummy dielectric layer, a dummy gate layer, and a mask layer are sequentially formed on the fin strips 101a, the semiconductor sheets 310, and the channel layers 210. The dummy dielectric layer is formed on the fin strips 101a, the semiconductor sheets 310, and the channel layers 210. The dummy dielectric layer may be formed of a dielectric material such as silicon oxide, silicon nitride, a combination thereof, or the like, which may be deposited or thermally grown according to acceptable techniques.

Subsequently, the dummy gate layer may be deposited over the dummy dielectric layer and then planarized, such as by a CMP. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer.

Subsequently, the mask layer may be deposited over the dummy gate layer. The mask layer may be formed of a dielectric material such as silicon nitride, silicon oxynitride, or the like. The mask layer is patterned using acceptable photolithography and etching techniques to form masks 76. The pattern of the masks 76 can be then transferred to the dummy gate layer by any acceptable etching technique to form dummy gates 74. The pattern of the masks 76 may optionally be further transferred to the dummy dielectric layer by any acceptable etching technique to form dummy dielectrics 72. The dummy gates 74 cover portions of the semiconductor sheets 310 and the channel layers 210 that will be exposed in subsequent processing to form active regions. The dummy gates 74 may also have lengthwise directions substantially perpendicular (within process variations) to the lengthwise directions of the fin strips 101a. The masks 76 can optionally be removed after patterning, such as by any acceptable etching technique.

The gate spacers 233 can be formed over the semiconductor sheets 310 and the channel layers 210 and on exposed sidewalls of the masks 76 (if present), the dummy gates 74, and the dummy dielectrics 72. In some embodiments, the gate spacer 233 can be interchangeably referred to top spacers or upper gate spacers. In some embodiments, the gate spacer 233 may include multiple dielectric material and selected from a group consist of SiO₂, Si₃N₄, carbon doped oxide, nitrogen doped oxide, porous oxide, air gap, or combinations thereof. The gate spacer 233 may be formed by conformally depositing one or more dielectric material(s) and subsequently etching the dielectric material(s). Acceptable dielectric materials may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 74 (thus forming the layer 233a) to form the gate spacer 233.

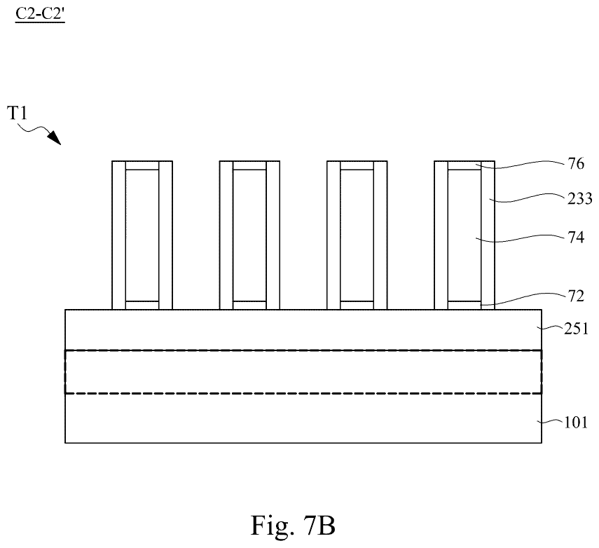

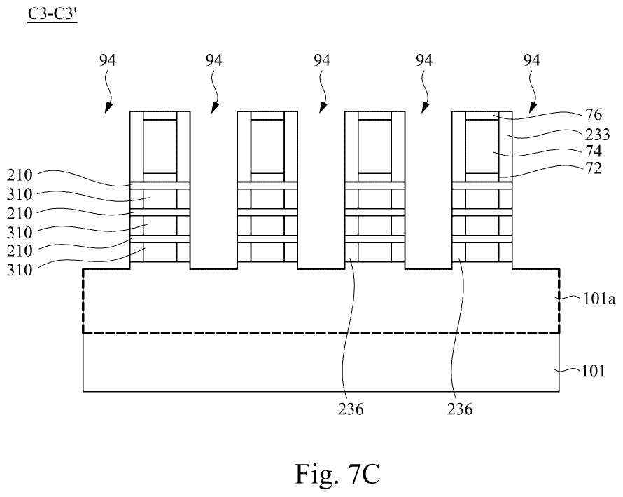

Reference is made to FIGS. 7A-7C. Source/drain recesses 94 can be formed in the semiconductor sheets 310 and the channel layers 210. In some embodiments, the source/drain recesses 94 extend through the semiconductor sheets 310 and the channel layers 210 and into the fin strips 101a. In some embodiments, the fin strips 101a may be etched such that bottom surfaces of the source/drain recesses 94 are disposed below the top surfaces of the STI structures 251. The source/drain recesses 94 may be formed by etching the semiconductor sheets 310 and the channel layers 210 using an anisotropic etching processes, such as a RIE, a NBE, or the like. The gate spacers 233 and the dummy gates 74 act as mask portions of the fin strips 101a, the semiconductor sheets 310, and the channel layers 210 during the etching processes used to form the source/drain recesses 94. A single etch process may be used to etch each of the semiconductor sheets 310 and the channel layers 210, or multiple etch processes may be used to etch the semiconductor sheets 310 and the channel layers 210. Timed etch processes may be used to stop the etching of the source/drain recesses 94 after the source/drain recesses 94 reach a desired depth.

Subsequently, inner spacers 236 are formed on sidewalls of the remaining portions of the semiconductor sheets 310, e.g., those sidewalls exposed by the source/drain recesses 94. As will be subsequently described in greater detail, source/drain regions will be subsequently formed in the source/drain recesses 94, and the semiconductor sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the semiconductor sheets 310.

As an example to form the inner spacers 236, the source/drain recesses 94 can be laterally expanded. Specifically, portions of the sidewalls of the semiconductor sheets 310 exposed by the source/drain recesses 94 may be recessed. Although sidewalls of the semiconductor sheets 310 are illustrated as being straight, the sidewalls may be concave or convex. The sidewalls may be recessed by any acceptable etching process, such as one that is selective to the material of the semiconductor sheets 310 (e.g., selectively etches the material of the semiconductor sheets 310 at a faster rate than the material of the channel layers 210). The etching may be isotropic. For example, when the channel layers 210 are formed of silicon and the semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the semiconductor sheets 310.

The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the gate spacer 233. In some embodiments, the material of inner spacer 236 is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the layer 233a, the outer sidewalls of the inner spacers 236 may extend beyond or be recessed from the sidewalls of the gate spacer 233. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

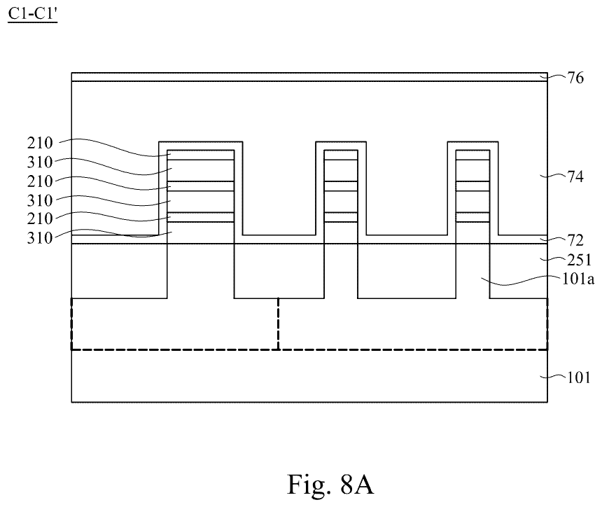

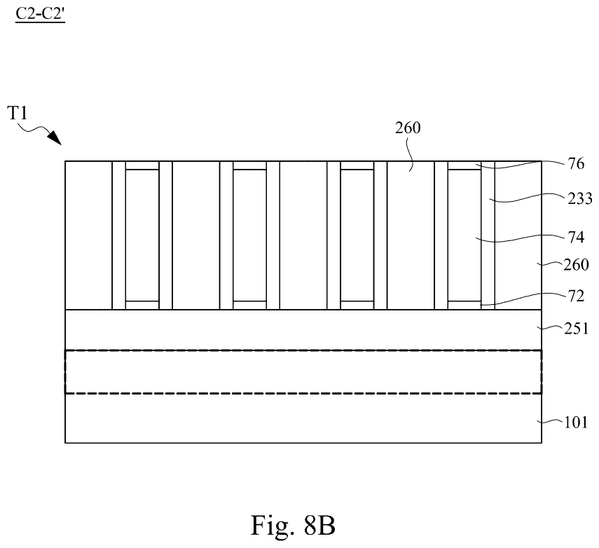

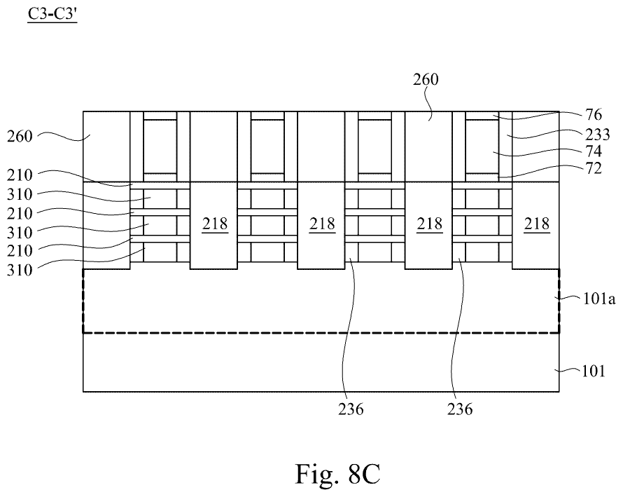

Reference is made to FIGS. 8A-8C. Source/drain regions 218 can be formed in the source/drain recesses 94, such that each dummy gate 74 (and corresponding channel layers) is disposed between respective adjacent pairs of the epitaxial source/drain regions 218. Subsequently, the layer 233b can be formed on the layer 233a, such that the layers 233a and 233b can be collectively referred to as the gate spacer 233 as top spacer. In some embodiments, the gate spacers 233 and the inner spacers 236 are used to separate the epitaxial source/drain regions 218 from, respectively, the dummy gates 74 and the semiconductor sheets 310 by an appropriate lateral distance so that the epitaxial source/drain regions 218 do not short out with subsequently formed gates of the resulting nano-FETs.

An inter-layer dielectric (ILD) layer 260 can be deposited over the epitaxial source/drain regions 218, the gate spacers 233, and the masks 76 (if present)/the dummy gates 74. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. In some embodiments, the ILD layer 260 may be made of an oxide, nitride, the like, or combinations thereof. Other insulation materials formed by any acceptable process may be used. In some embodiments, a contact etch stop layer (CESL) is formed between the ILD layer 260 and the epitaxial source/drain regions 218, the gate spacers 233, and the masks 76 (if present)/the dummy gates 74. The CESL may be formed of a dielectric material, such as silicon nitride, silicon oxide, silicon oxynitride, or the like, having a high etching selectivity from the etching of the ILD 260. The CESL may be formed by any suitable method, such as CVD, ALD, or the like.

Subsequently, a removal process is performed to level the top surfaces of the ILD layer 260 with the top surfaces of the masks 76 (if present)/the dummy gates 74.

In some embodiments, a planarization process such as a chemical mechanical polish (CMP), an etch-back process, combinations thereof, or the like may be utilized. After the removal process, the top surfaces of the gate spacers 233, the ILD layer 260, the CESL, and the masks 76 (if present)/the dummy gates 74 are coplanar (within process variations). Accordingly, the top surfaces of the masks 76 (if present)/the dummy gates 74 can be exposed through the ILD layer 260. In some embodiments, the masks 76 remain, and the planarization process levels the top surface of the ILD layer 260 with the top surfaces of the masks 76.

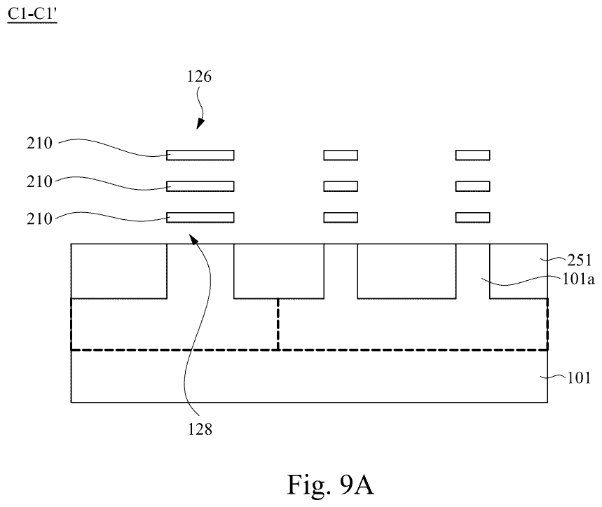

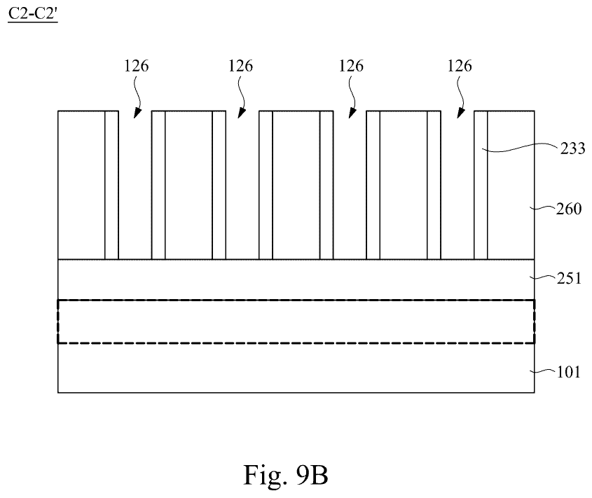

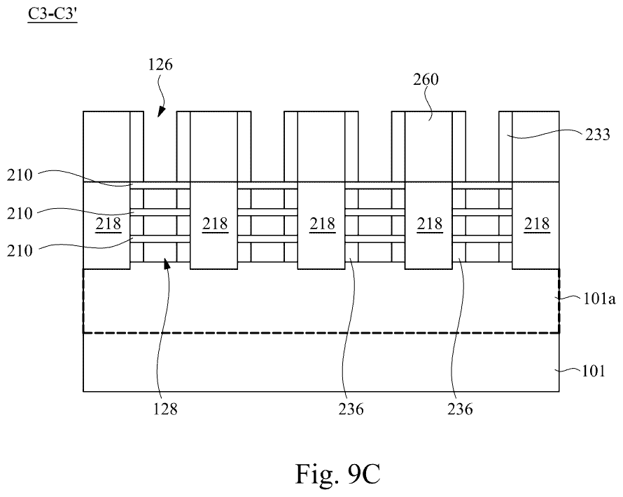

Reference is made to FIGS. 9A-9C. The masks 76 (if present) and the dummy gates 74 are removed in an etching process, so that recesses 126 are formed. Portions of the dummy dielectrics 72 can also be removed. In some embodiments, the dummy gates 74 are removed by an anisotropic dry etch process. For example, the etching process may include a dry etch process using reaction gas(es) that selectively etch the dummy gates 74 at a faster rate than the ILD layer 260 and the gate spacers 233. During the removal, the dummy dielectrics 72 may be used as etch stop layers when the dummy gates 74 are etched. The dummy dielectrics 72 are then removed. Each recess 126 can expose and/or overlies portions of the channel layers 210 disposed between adjacent pairs of the epitaxial source/drain regions 218.

The remaining portions of the semiconductor sheets 310 are then removed to expand the recesses 126, such that openings 128 are formed in regions between the channel layers 210. The remaining portions of the semiconductor sheets 310 can be removed by any acceptable etching process that selectively etches the material of the semiconductor sheets 310 at a faster rate than the material of the channel layers 210. The etching may be isotropic. For example, when the semiconductor sheets 310 are formed of silicon germanium and the channel layers 210 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the channel layers 210. In some embodiments, the removing of the remaining portions of the semiconductor sheets 310 can be interchangeably referred to as a channel releasing process. The channel layers 210 can be interchangeably referred to as a vertically stacked multiple channels (sheets) and may have a vertically sheet pitch within a range of from about 10 nm to about 30 nm. In some embodiments, the channel layers 210 may have a thickness within a range from about 4 nm to about 10 nm. In some embodiments, the vertically sheet pitch of the between adjacent two of the channel layers 210 may be within a range from about 6 to about 20 nm.

Reference is made to FIGS. 10A-10C. Gate structures 220 are formed to wrap around the channel layers 210. The gate structure 220 can include a gate dielectric layer 220a formed in the recesses 126 and a gate electrode layer 220b formed on the gate dielectric layer 220a. The gate dielectric layer 220a and the gate electrode layers 220b are layers for replacement gates, and each wrap around all (e.g., four) sides of the second channel layer 210. Specifically, the gate dielectric layer 220a is disposed on the sidewalls and/or the top surfaces of the fin strips 101a; on the top surfaces, the sidewalls, and the bottom surfaces of the channel layers 210; and on the sidewalls of the gate spacers 233. Subsequently, the gate electrode layer 220b is formed over the gate dielectric layer 220a. In some embodiments, material and manufacturing method of the gate dielectric layer 220a and the gate electrode layer 220b are substantially the same as that shown in FIGS. 4A-4C, and the related detailed descriptions may refer to the foregoing paragraphs, and are not described again herein for the purpose of simplicity and clarity.

Subsequently, a removal process is performed to remove the excess portions of the materials of the gate dielectric layer 220a and the gate electrode layers 220b, which excess portions are over the top surfaces of the ILD layer 260 and the gate spacers 233, thereby forming gate dielectric layer 220a and gate electrode layers 220b. In some embodiments, a planarization process such as a chemical mechanical polish (CMP), an etch-back process, combinations thereof, or the like may be utilized. The gate dielectric layer 220a, when planarized, has portions left in the recesses 126. The gate electrode layers 220b, when planarized, have portions left in the recesses 126. The top surfaces of the gate spacers 233, the CESL (not shown), the ILD layer 260, the gate dielectric layer 220a, and the gate electrodes can be coplanar (within process variations). The gate dielectric layer 220a and the gate electrode layers 220b form replacement gates of the resulting nano-FETs. In some embodiments, the gate electrode layers 220b each have a gate length in a range from about 6 nm to about 20 nm.

Reference is made to FIGS. 11A-11D. The CMG structure 140/142 can be formed as a gate-cut structure (e.g., portion 140a of the CMG structure 140 shown in FIGS. 11A and 11C) and a channel-cut structure (e.g., portions 140b through 140e shown in FIGS. 11A, 11B, and 11D) for the gate structure 220 and the channel layer 210. In some embodiments, the CMG structures 140 and 142 can be formed by a cut metal gate (CMG) process. Portions of the gate electrode layers 220b and the gate dielectric layers 220a are removed to reappear portions of the gate trenches with the gate spacers 233 as their sidewalls. The isolation region may be formed by using a removing process. In the removing process, the gate electrode layer 220b and the gate dielectric layer 220a can be etched anisotropically, until underlying fin strip 101a and/or the STI structure 251 are exposed. In some embodiments, as shown in FIGS. 11B and 11D, the fin strip 101a is then etched, and the etching continues down into the underlying substrate 101.

In some embodiments, the portions of the gate electrode layers 220b and the gate dielectric layer 220a may be removed by dry etching, wet etching, or a combination of dry and wet etching. For example, a wet etching process may include exposure to a hydroxide containing solution (e.g., ammonium hydroxide), deionized water, and/or other suitable etchant solutions. Subsequently, a dielectric material is deposited into the gate trenches, followed by a planarization process to remove excess portions of the dielectric material. The remaining dielectric material forms the CMG structure 140/142. Some of the gate structures 220 can be replaced by the CMG structure 140/142 to form an isolation region separating the source/drain regions of neighboring semiconductor devices from each other. In some embodiment, a top surface of the CMG structure 140/142 can be level with a top surface of the gate structure 220.

In some embodiments, the deposition of the dielectric material of the CMG structure 140/142 can be performed using a deposition process such as chemical vapor deposition (CVD), physical vapor deposition (PVD), atomic layer deposition (ALD), high density plasma CVD (HDPCVD), metal organic CVD (MOCVD), or plasma enhanced CVD (PECVD), or the like. In some embodiments, material of the CMG structure 140 can be substantially the same as that shown in FIGS. 4A-4C, and the related detailed descriptions may refer to the foregoing paragraphs, and are not described again herein for the purpose of simplicity and clarity.

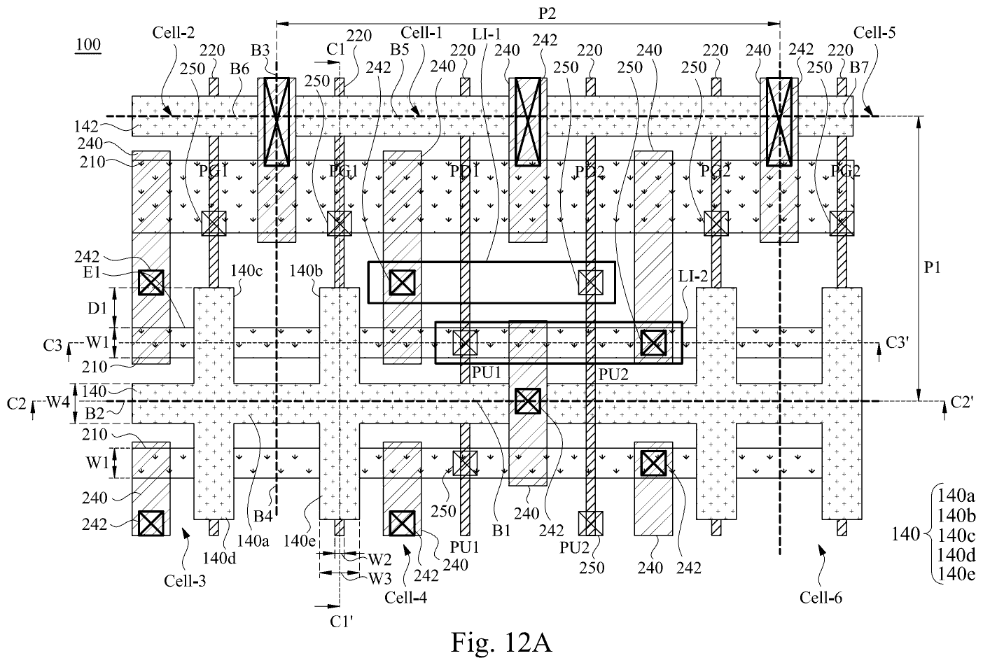

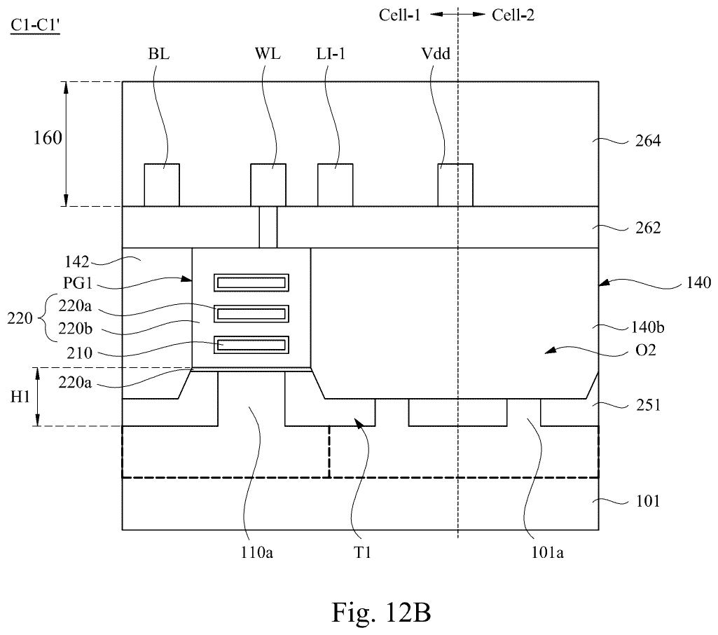

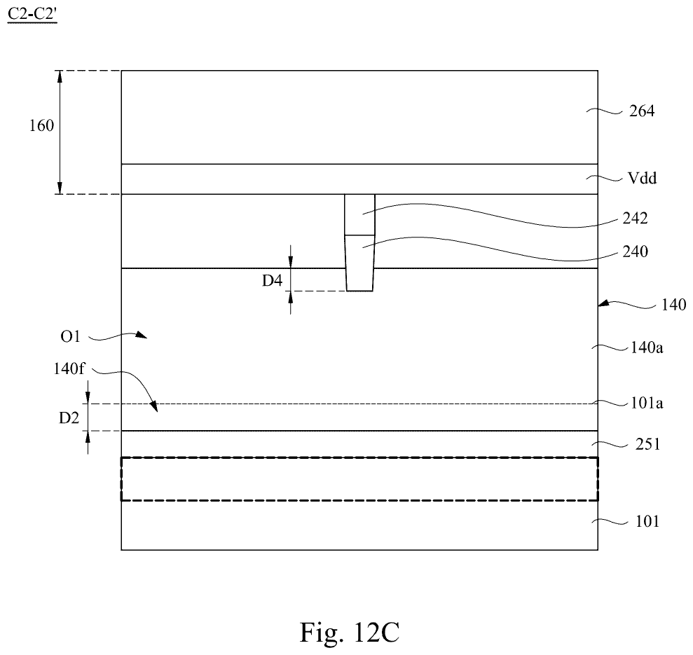

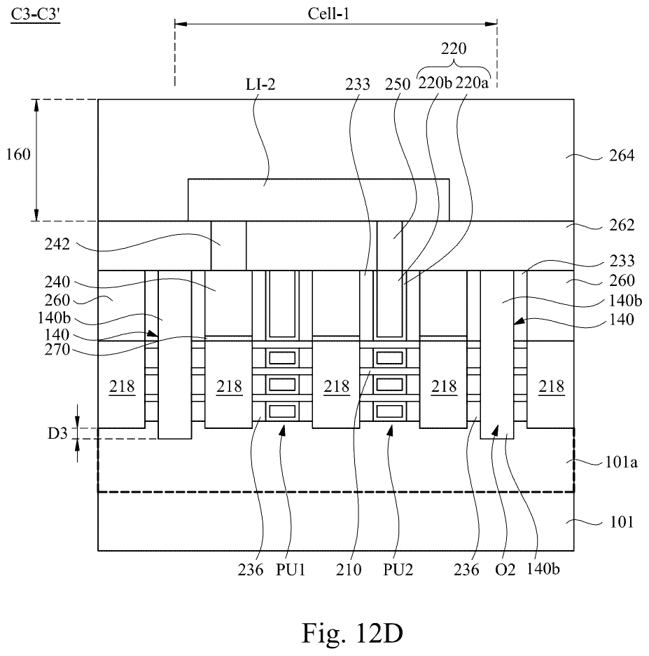

Reference is made to FIGS. 12A-12D. Source/drain contacts 240 can be formed in the ILD layer 260. In some embodiments, a source/drain silicide region 270 can be formed to sandwich between the source/drain region 218 and the source/drain contact 240. Subsequently, an ILD layer 262 may be deposited over the ILD layer 260, the source/drain contacts 240, and the CMG structure 140. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, a source/drain via 242 may be formed in the ILD layer 262 and on the corresponding source/drain contact 240, and a gate via 250 may be formed to pass through the ILD layer 262 and land on the gate structure 220. In some embodiments, the source/drain contacts 240, the source/drain via 242, and/or the gate via 250 may include a metal-containing material such as titanium nitride, titanium oxide, tungsten, cobalt, ruthenium, aluminum, copper, combinations thereof, multi-layers thereof, or the like.

Subsequently, an interconnect structure 160 including metal lines and vias can be formed over the ILD layer 262 to electrically connect to the corresponding gate vias 250 or the corresponding source/drain vias 242. The metal lines can include the power supply voltage lines Vdd, the local connection line LI-1, the bit-line BL, and the word-line WL. In some embodiments, materials of the metal lines and vias may be made of a conductive material, such as Cu, Co, Ru, Pt, Al, W, Ti, TaN, TiN, or any combinations thereof. Also included in the interconnect structure is an inter-metal dielectric (IMD) layer 264. The IMD layer 264 may provide electrical insulation as well as structural support for the various features of the interconnect structure. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 264 may be made of an oxide, nitride, the like, or combinations thereof.

As an example to form the conductive lines in the interconnect structure, trenches/openings for the conductive lines are formed through the IMD layer. The trenches/openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the IMD layer. The remaining liner and conductive material form the conductive lines in the trenches/openings. The conductive lines may be formed in distinct processes, or may be formed in the same process. In some embodiments, material and manufacturing method of the conductive lines (not shown) in other metallization layers are substantially the same as those of the conductive line in the first metallization layer as shown in FIGS. 12A-12D, and the related detailed descriptions may refer to the foregoing paragraphs, and are not described again herein for the purpose of simplicity and clarity and does not in itself dictate a relationship between the various embodiments and/or configurations discussed.

Reference is made to FIG. 13. FIG. 13 illustrates a cell array layout diagram of a SRAM circuit in accordance with some embodiments of the present disclosure. While FIG. 13 illustrates an embodiment of a semiconductor structure 300 with different CMG structure configurations than the semiconductor structure 100 in FIGS. 2A-12D, the present disclosure may repeat reference numerals and/or letters in the various examples. This repetition is for the purpose of simplicity and clarity and does not in itself dictate a relationship between the various embodiments and/or configurations discussed.

The difference highlighted in FIG. 13 includes a modification to the CMG structure 340, particularly the omission of segments of the portion 140a as shown in FIG. 2A. These omitted segments of portion 140a are between the portion 140b and the portion 140c, between the portion 140d and the portion 140e, and extend from boundary B1 to boundary B2 as shown in FIG. 2A, allowing the CMG structure 340 to achieve a T-shape profile when viewed from above, as illustrated in FIG. 13. This alteration may affect the continuous nature of the CMG structure 140 as shown in FIG. 2A, potentially influencing the electrical isolation and structural integrity between adjacent SRAM cells. By removing specific segments of the portion 140a, the design may allow for increased flexibility in how other components of the CMG structure, like the portions 140b, 140c, 140d, and 140e, are arranged or scaled, which in turn allows for optimizing the space within the semiconductor layout and adapting the design to specific fabrication or performance requirements.

Reference is made to FIG. 14. FIG. 14 illustrates a cell array layout diagram of a SRAM circuit in accordance with some embodiments of the present disclosure. While FIG. 14 illustrates an embodiment of a semiconductor structure 400 with different CMG structure configurations than the semiconductor structure 100 in FIGS. 2A-12D, the present disclosure may repeat reference numerals and/or letters in the various examples. This repetition is for the purpose of simplicity and clarity and does not in itself dictate a relationship between the various embodiments and/or configurations discussed.

The difference highlighted in FIG. 14 includes a modification to the CMG structure 440, particularly the omission of the portions 140b, 140c, 140d, and 140e of the CMG structure 140 as shown in FIG. 2A, and these portions can act in segmenting and isolating channel regions within individual SRAM cells Cell-1, Cell-2, Cell-3, and Cell-4. Additionally, new elements, such as portions 440f and 440g, can be introduced in the CMG structure 440, and these new portions can extend from the first portion 140a of the CMG structure 440, allowing the CMG structure 440 to achieve an cross-shape profile when viewed from above, as depicted in FIG. 14. Specifically, the portion 440f can be located at a boundary B3 between the SRAM cells Cell-1 and Cell-2, and the portion 440g can be located at a boundary B4 between the SRAM cells Cell-3 and Cell-4. The portions 440f and 440g can cut off and isolate the corresponding channel regions 210 at the boundaries B3 and B4 between the SRAM cells. This modification can enhance SRAM cell performance by preventing electrical interference between adjacent SRAM cells. After severing the channel regions 210, the portions 440f and 440g of the CMG structure 440 can extend beyond the edge of these regions by at least half the width W1 of the channel regions 210, ensuring that no metal residue remain that could potentially cause short-circuiting or other electrical failures. By way of example and not limitation, the second portion 440f of the CMG structure 440 not only can cut off the channel region 210 at the boundary B3 and B4 between the SRAM cells Cell-1 and Cell-2 but also extend beyond the edge E1 of the channel region 210 by the dimension D1 that is greater than half of the width W1, in a range from about 5 to 10 nm, such as about 5, 6, 7, 8, 9, or 10 nm.

Reference is made to FIG. 15. FIG. 15 illustrates a cell array layout diagram of a SRAM circuit in accordance with some embodiments of the present disclosure. While FIG. 15 illustrates an embodiment of a semiconductor structure 500 with different CMG structure configurations than the semiconductor structure 100 in FIGS. 2A-12D, the present disclosure may repeat reference numerals and/or letters in the various examples. This repetition is for the purpose of simplicity and clarity and does not in itself dictate a relationship between the various embodiments and/or configurations discussed.

As shown in FIG. 15, the difference between the embodiment in FIG. 15 and the embodiment in FIGS. 2A-12D is in that the second portion 140b, the third portion 140c, the fourth portion 140d, and the fifth portion 140e of the CMG structure 140 can be widen along the X-direction to selectively replace at least part or all of the adjacent source/drain regions 218 as shown in FIG. 2A to achieve an cross-shape profile (or a rectangular profile) when viewed from above, as depicted in FIG. 15. Specifically, the second portion 140b as shown in FIG. 2A can widen towards the third portion 140c, eventually merging into an integrated portion 540f as shown in FIG. 15, ensuring that the source/drain region 218, which originally lies between the second portions 140b and 140c as shown in FIG. 2A, can be fully encompassed and replaced by the CMG structure 540. Similarly, the fourth portion 140d as shown in FIG. 2A can widen towards the fifth portion 140e, eventually merging into an integrated portion 540g as shown in FIG. 15, ensuring that the source/drain region 218, which originally lies between the second portions 140d and 140e as shown in FIG. 2A, can be fully encompassed and replaced by the CMG structure 540, thereby streamlining the structural design and improving the electrical characteristics of the memory cell.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an improved SRAM layout with a CMG structure featuring, such as H-shape, T-shape, cross-shape, and square top view profiles, can enhance the reliability and performance of semiconductor devices. By adjusting the CMG structure profiles, the tolerance window for manufacturing issues like peeling and cut fails can be enlarged, leading to more robust gate structures. The CMG structure of the present disclosure can helps minimize CPD layout effects and mitigate metal boundary effects between pass-gate and pull-down transistors, thus improving circuit reliability and performance consistency.

In some embodiments, a method includes forming a first channel pattern over a substrate; forming a first gate pattern extending across the first channel pattern, and a second gate pattern extending across the first channel pattern; forming a plurality of source/drain patterns adjoining the first channel pattern; depositing a dielectric layer over the source/drain patterns and laterally surrounding the first and second gate patterns; performing an etching process on the dielectric layer, the first and second gate patterns, and the first channel pattern to form a first trench and a second trench, wherein when viewed from above, the first trench extends longitudinally along the first channel pattern and intersects the first and second gate patterns, thereby severing the first and second gate patterns, and the second trench initiates from the first trench, takes the place of a first segment of the first gate pattern, and severs the first channel pattern originally beneath the first segment of the first gate pattern; filling a dielectric material in the first and second trenches to form a gate isolation structure, wherein the gate isolation structure has a first portion in the first trench and a second portion in the second trench. In some embodiments, the etching process is performed after forming the source/drain patterns. In some embodiments, the method further includes forming a second channel pattern over the substrate, wherein after the etching process, the first gate pattern has a second segment across the second channel pattern, and the second gate pattern has a first segment across the first channel pattern and a second segment across the second channel pattern. In some embodiments, the first portion of the gate isolation structure is positioned at a side of the first channel pattern opposite to the second channel pattern. In some embodiments, the second segment of the first gate pattern across the second channel pattern forms a pass-gate transistor, the first segment of the second gate pattern across the first channel pattern forms a pull-up transistor, and the second segment of the second gate pattern across the second channel pattern forms a pull-down transistor. In some embodiments, the method further includes forming a third gate pattern extending across the first channel pattern, wherein the etching process is performed to form a third trench that initiates from the first trench, takes the place of the third gate pattern, and severs the first channel pattern originally beneath the third gate pattern. In some embodiments, the dielectric material further fills in the third trench to expand the gate isolation structure comprising a third portion in the third trench, collectively forming an H-shape profile when viewed from above with the first and second portions of the gate isolation structure. In some embodiments, the second portion of the gate isolation structure extends beyond an edge of the first channel pattern by a distance that is at least half a width of the first channel pattern. In some embodiments, the distance is in a range from about 5 to 10 nm. In some embodiments, when viewed from above, the first portion of the gate isolation structure has a width increasing as a distance from the second portion of the gate isolation structure decreases.

In some embodiments, a method includes forming a first semiconductive sheet over a first memory cell region of a substrate, and a second semiconductive sheet over a second memory cell region of the substrate, wherein the first and second memory cells are arranged along a direction perpendicular to a lengthwise direction of the first semiconductive sheet; growing a plurality of first epitaxial structures on opposite sides of the first semiconductive sheet, and a plurality of second epitaxial structures on opposite sides of the second semiconductive sheet; forming a first gate strip wrapping around the first semiconductive sheet, and a second gate strip wrapping around the second semiconductive sheet; forming a cut metal gate structure over the substrate, wherein when viewed from above, the cut metal gate structure has a first longitudinal portion extends from a longitudinal end of the first gate strip to a longitudinal end of the second gate strip, and a second longitudinal portion initiating from the first longitudinal portion and extending along the lengthwise direction of the first semiconductive sheet. In some embodiments, the first longitudinal portion of the cut metal gate structure is in contact with the longitudinal end of the first gate strip. In some embodiments, when viewed from above, the first and second longitudinal portions of the cut metal gate structure collectively form a T-shape profile. In some embodiments, forming the cut metal gate structure is performed after growing the first and second epitaxial structures. In some embodiments, the cut metal gate structure comprises SiO₂, SiCO, SiO2:F, SiN, SiCN, oxide, nitrogen, and a carbon-based material, or combinations thereof.

In some embodiments, the semiconductor structure includes a substrate, a first memory cell, a second memory cell, a third memory cell, and a cut metal gate structure. The first memory cell is over the substrate, wherein the first memory cell comprises a first pass-gate transistor and a first pull-up transistor. The second memory cell is over the substrate and forms a first boundary with the first memory cell, wherein the second memory cell comprises a second pull-up transistor. The third memory cell is over the substrate and forms a second boundary with the first memory cell, wherein the second memory cell comprises a second pass-gate transistor. The cut metal gate structure is over the substrate, wherein when viewed from above, the cut metal gate structure has a first portion extends along a direction perpendicular to a lengthwise direction of a gate of the first pass-gate transistor and interposes between a gate of the first pull-up transistor and a gate of the second pull-up transistor, and has a second portion extends along the lengthwise direction of the gate of the first pass-gate transistor and between the first and third memory cells. In some embodiments, when viewed from above, the first and second portions of the cut metal gate structure collectively form a cross-shape profile. In some embodiments, the second portion of the cut metal gate structure is spaced apart from the gate of the first pass-gate transistor and a gate of the second pass-gate transistor. In some embodiments, the second portion of the cut metal gate structure is in contact with a longitudinal end of the gate of the first pass-gate transistor and a longitudinal end of a gate of the second pass-gate transistor. In some embodiments, when viewed from above, the second portion of the cut metal gate structure has a width measured in the direction, and the width is greater than a distance between the gate of the first pass-gate transistor and of a gate of the second pass-gate transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first channel pattern over a substrate;
forming a first gate pattern extending across the first channel pattern, and a second gate pattern extending across the first channel pattern;
forming a plurality of source/drain patterns adjoining the first channel pattern;
depositing a dielectric layer over the source/drain patterns and laterally surrounding the first and second gate patterns;
performing an etching process on the dielectric layer, the first and second gate patterns, and the first channel pattern to form a first trench and a second trench, wherein when viewed from above, the first trench extends longitudinally along the first channel pattern and intersects the first and second gate patterns, thereby severing the first and second gate patterns, and the second trench initiates from the first trench, takes the place of a first segment of the first gate pattern, and severs the first channel pattern originally beneath the first segment of the first gate pattern; and
filling a dielectric material in the first and second trenches to form a gate isolation structure, wherein the gate isolation structure has a first portion in the first trench and a second portion in the second trench.

2. The method of claim 1, wherein the etching process is performed after forming the source/drain patterns.

3. The method of claim 1, further comprising:
forming a second channel pattern over the substrate, wherein after the etching process, the first gate pattern has a second segment across the second channel pattern, and the second gate pattern has a first segment across the first channel pattern and a second segment across the second channel pattern.

4. The method of claim 3, wherein the first portion of the gate isolation structure is positioned at a side of the first channel pattern opposite to the second channel pattern.

5. The method of claim 3, wherein the second segment of the first gate pattern across the second channel pattern forms a pass-gate transistor, the first segment of the second gate pattern across the first channel pattern forms a pull-up transistor, and the second segment of the second gate pattern across the second channel pattern forms a pull-down transistor.

6. The method of claim 1, further comprising:
forming a third gate pattern extending across the first channel pattern, wherein the etching process is performed to form a third trench that initiates from the first trench, takes the place of the third gate pattern, and severs the first channel pattern originally beneath the third gate pattern.

7. The method of claim 6, wherein the dielectric material further fills in the third trench to expand the gate isolation structure comprising a third portion in the third trench, collectively forming an H-shape profile when viewed from above with the first and second portions of the gate isolation structure.

8. The method of claim 1, wherein the second portion of the gate isolation structure extends beyond an edge of the first channel pattern by a distance that is at least half a width of the first channel pattern.

9. The method of claim 8, wherein the distance is in a range from about 5 to 10 nm.

10. The method of claim 1, wherein when viewed from above, the first portion of the gate isolation structure has a width increasing as a distance from the second portion of the gate isolation structure decreases.

11. A method, comprising:
forming a first semiconductive sheet over a first memory cell region of a substrate, and a second semiconductive sheet over a second memory cell region of the substrate, wherein the first and second memory cells are arranged along a direction perpendicular to a lengthwise direction of the first semiconductive sheet;
growing a plurality of first epitaxial structures on opposite sides of the first semiconductive sheet, and a plurality of second epitaxial structures on opposite sides of the second semiconductive sheet;
forming a first gate strip wrapping around the first semiconductive sheet, and a second gate strip wrapping around the second semiconductive sheet; and
forming a cut metal gate structure over the substrate, wherein when viewed from above, the cut metal gate structure has a first longitudinal portion extends from a longitudinal end of the first gate strip to a longitudinal end of the second gate strip, and a second longitudinal portion initiating from the first longitudinal portion and extending along the lengthwise direction of the first semiconductive sheet.

12. The method of claim 11, wherein the first longitudinal portion of the cut metal gate structure is in contact with the longitudinal end of the first gate strip.

13. The method of claim 11, wherein when viewed from above, the first and second longitudinal portions of the cut metal gate structure collectively form a T-shape profile.

14. The method of claim 11, wherein forming the cut metal gate structure is performed after growing the first and second epitaxial structures.

15. The method of claim 11, wherein the cut metal gate structure comprises SiO₂, SiCO, SiO2:F, SiN, SiCN, oxide, nitrogen, and a carbon-based material, or combinations thereof.

16. A semiconductor structure, comprising:
a substrate;
a first memory cell over the substrate, wherein the first memory cell comprises a first pass-gate transistor and a first pull-up transistor;
a second memory cell over the substrate and forming a first boundary with the first memory cell, wherein the second memory cell comprises a second pull-up transistor;
a third memory cell over the substrate and forming a second boundary with the first memory cell, wherein the second memory cell comprises a second pass-gate transistor; and
a cut metal gate structure over the substrate, wherein when viewed from above, the cut metal gate structure has a first portion extends along a direction perpendicular to a lengthwise direction of a gate of the first pass-gate transistor and interposes between a gate of the first pull-up transistor and a gate of the second pull-up transistor, and has a second portion extends along the lengthwise direction of the gate of the first pass-gate transistor and between the first and third memory cells.

17. The semiconductor structure of claim 16, wherein when viewed from above, the first and second portions of the cut metal gate structure collectively form a cross-shape profile.

18. The semiconductor structure of claim 16, wherein the second portion of the cut metal gate structure is spaced apart from the gate of the first pass-gate transistor and a gate of the second pass-gate transistor.

19. The semiconductor structure of claim 16, wherein the second portion of the cut metal gate structure is in contact with a longitudinal end of the gate of the first pass-gate transistor and a longitudinal end of a gate of the second pass-gate transistor.

20. The semiconductor structure of claim 16, wherein when viewed from above, the second portion of the cut metal gate structure has a width measured in the direction, and the width is greater than a distance between the gate of the first pass-gate transistor and of a gate of the second pass-gate transistor.
